(19) United States
(12) Patent Application Publication
(10) Pub. No.: US 2011/0055646 A1
(43) Pub. Date: Mar. 3, 2011

(54) FAULT DIAGNOSIS IN A MEMORY BIST ENVIRONMENT

(76) Inventors: Nilanjan Mukherjee, Wilsonville, OR (US); Artur Pogiel, Szubin (PL); Janusz Rajski, West Linn, OR (US); Jerzy Tyszer, Poznan (PL)

(21) Appl. No.: 12/678,747

(22) PCT Filed: Sep. 18, 2008
(86) PCT No.: PCT/US08/76911

§ 371 Date: Jul. 8, 2010

Related U.S. Application Data
(60) Provisional application No. 60/973,432, filed on Sep. 18, 2007.

(51) Int. Cl. G11C 29/12; G06F 11/27

(52) U.S. Cl. 714/719; 714/E11.169

(57) ABSTRACT

Disclosed are methods and devices for temporally compacting test response signatures of failed memory tests in a memory built-in self-test environment, to provide the ability to carry on memory built-in self-test operations even with the detection of multiple time related memory test failures. In some implementations of the invention, the compacted test response signatures are provided to an automated test equipment device along with memory location information. According to various implementations of the invention, an integrated circuit with embedded memory (204) and a memory BIST controller (206) also includes a linear feed-back structure (410) for use as a signature register that can temporally compact test response signatures from the embedded memory array during a test step of a memory test. In various implementations the integrated circuit may also include a failing words counter (211), a failing column indicator (213), and/or a failing row indicator (214) to collect memory location information for a failing test response.

### RELATED APPLICATIONS

This application claims priority under 35 U.S.C. §119 to U.S. Provisional Patent Application No. 60/973,432, entitled “Fault Diagnosis in a Memory BIST Environment,” filed on Sep. 18, 2007, and naming Nilanjan Mukherjee, Artur Pogiel, Janusz Rajski, and Jerzy Tyszer as inventors, which application is incorporated herein by reference in its entirety.

### FIELD OF THE INVENTION

The present invention is directed to memory fault diagnosis in a memory built-in self-test environment. Aspects of the invention have particular applicability to the collection and analysis of test data so as to provide for continuous at-speed testing of embedded memory in integrated circuit devices.

### BACKGROUND OF THE INVENTION

Embedded memories are often parts of many integrated circuit devices. For example, System-on-a-Chip (SoC) devices typically contain a number of embedded memory systems. The embedded memory systems include a set of memory cells, which are components capable of retaining a state, typically characterized by a high voltage value or a low voltage value that can represent a binary digit (bit) of 0 or 1, respectively. The memory cells are arranged in an embedded memory in the form of an array, often specified in terms of a row and a column. Data lines can apply or read the voltage values on specified cells to store or retrieve a bit value, respectively. Memory cells are furthermore typically arranged into words, that is, a fixed number of cells that are addressed simultaneously as a single unit.

FIG. 1 shows an example of a memory architecture 100 that may be used in an embedded memory. Each word in the memory has an address. A row decoder 101a receives address data 102a for an addressed word and upon decoding the address data, asserts a data line or interconnect for the addressed row. Likewise, a column decoder 101b receives address data 102b for the addressed word. Based on the address data, the column decoder 101b asserts a data line or interconnect for columns corresponding to the addressed word. Upon receipt of a clock signal, for example, the memory address is accessed, for storage or retrieval of a data word 103 in the memory array 104.

Every row consists of W words, each B bits long, with R rows in all. Consecutive bits belonging to one word can be either placed one after another or be interleaved forming segments 105, as illustrated in FIG. 1. That is, bits belonging to successive words can be interleaved in respective memory array rows. Thus, in interleaved format, corresponding bits of words are configured together into segments 105. In the example memory architecture shown, exactly one bit in each segment is addressed when a word of a row in memory is addressed. That is, in any given row the first b₀ of the first segment, the first b₁ of the second segment, and so on to the first b_{B-1} of the B^{th} segment, are addressed when the first word of that row is addressed.

Recently, a rapid increase in the chip area occupied by memory arrays has been observed. Following this trend, the International Technology Roadmap for Semiconductors predicts that memories will take up more than 90% of the silicon area of some chips within the decade. Due to their extremely large scale of integration, memory arrays have already started introducing new yield loss mechanisms at a rate, magnitude, and complexity large enough to demand major changes in test strategies. Indeed, many types of failures, such as time-related or complex read faults, often not seen earlier, originate in the highest density areas of semiconductor chips. Thus, the capability to test current and future embedded memory systems is even more important than in previous generations of embedded memory systems.

In contrast to stand-alone memory units, however, embedded memory systems are more difficult to test and diagnose. This difficulty arises not only because of the more complex structure of embedded memories, but also because of the decreasing number of inputs and outputs available to access and control these circuits, resulting in a reduced bandwidth of test channels. Memory built-in self-test (MBIST) has become a desirable solution for performing high quality testing. Among the reasons that MBIST typically is a desirable option are the following: (1) embedded memory comprises regular structures that do not require application of sophisticated test patterns, so test stimuli and expected test responses can be generated, compressed, and stored by a relatively simple testing circuitry that incurs small hardware overhead; (2) a reduced number of input/output channels usually suffice to control the necessary BIST operations such as activation, scan-in, scan-out, and others; and (3) the entire test logic can be located on-chip, which enables testing to be performed at-speed thus allowing detection of time-related faults. One implementation of memory BIST testing is described in U.S. Pat. No. 6,421,794, “Method and Apparatus for Diagnosing Memory Using Self-Testing Circuits,” John T. Chen and Janusz Rajski, issued Jul. 16, 2002, which is hereby incorporated herein by reference in its entirety.

Although certain MBIST controllers are designed as hardwired finite state machines (FSM), some flexibility usually is desired. Consequently, many MBIST implementations are programmable (micro-coded) devices. Such circuits can be conveniently programmed to meet challenges of up-to-date embedded memory structures.

Fault diagnosis for embedded memories, known as built-in self-diagnosis (BISD), typically involves certain modifications in a conventional MBIST flow aimed mainly at determining incorrect test responses (sometimes generally referred to as failing patterns), that can indicate faulty memory cells, faulty memory array columns, or faulty memory array rows. The process of identifying failing sites of a memory array can be performed either on chip or, alternatively, off line, for example in automatic test equipment (ATE), or another diagnostic tool, after downloading compressed test responses (sometimes referred to as “signatures”) from a chip. Signatures corresponding to incorrect test responses, whether compressed or not, may be referred to herein as “failing signatures.” Fault diagnosis is carried out mainly to “repair” faulty memory arrays by replacing faulty rows or columns with spare ones in a built-in self-repair (BISR) process. Fault diagnosis is also carried out to facilitate modifying an existing fabrication process, for example, to improve future manufacturing yield.

In order to test a memory circuit for time-related faults, it is desirable to perform testing “at-speed,” that is, at the rated functional speed of the memory circuit. However, relatively low bandwidth at the I/O channels of the integrated circuit device can make it difficult or impossible to quickly download failing signatures or address locations of failing sites of the embedded memory. This problem grows in significance when another fault is detected while downloading previously obtained diagnostic data. Consequently, many BIST schemes modified to test memory circuits employ either a “pause and resume” mode of operation or a “stop and restart” mode of operation.

In a “pause and resume” mode, if there is, for example, only a single register to store the incorrect test response, the BIST controller goes into a hold mode when a failure is encountered. Once the incorrect test response is scanned out from the single register to the ATE, the BIST controller resumes its operations. In some BIST schemes, multiple registers are provided to store multiple incorrect test responses. When this is the case, the BIST controller can continue to test while encountering failures, until the registers are filled. The BIST controller then enters the hold mode until the contents of all the failure storage registers have been completely scanned out, and subsequently resumes its testing operations.

In a “stop and restart” mode, the BIST controller moves to an initial test state once a fault is detected, and the corresponding diagnostic data is scanned out. The rationale is that the BIST controller could otherwise miss timing related defects between the address where a fault was most recently detected and the next target location (where the BIST controller could resume its operations). In successive repetitions the BIST controller does not monitor the memory output until the address of the most recently detected fault is passed.

It is worth noting that certain single faults may produce large amounts of diagnostic data. For example, a failure in just one signal line or “interconnect” could result in an entire row or column of the memory array working incorrectly, producing a great deal of erroneous data. Hence, there are two primary concerns regarding a high volume of diagnosis data with respect to conventional memory BIST. First of all, it may take a significant amount of time to scan the data out. Second, the ATE memory may get filled up very quickly, especially if all memory failures are being recorded. Thus, either the data has to be truncated, or the memory BIST controller has to stop so that the ATE memory can be unloaded. Truncation of data is typically not acceptable from a diagnostic point of view. Indeed, all of the diagnostic data usually is needed to analyze failures to decide whether a given memory is repairable. Also, a lengthy unloading of the ATE memory is often unacceptable due to time constraints.

### BRIEF SUMMARY OF THE INVENTION

Various aspects of the invention relate to techniques and devices for temporally compacting test response signatures of failed memory tests in a memory built-in self-test environment, to provide the ability to carry on memory built-in self-test operations even with the detection of multiple time related memory test failures. In some implementations of the invention, the compacted test response signatures are provided to an ATE along with memory location information. A diagnostic tool may receive the compacted test response signatures and memory location information from the ATE. Then, using the memory location information, the diagnostic tool may select an appropriate diagnostic procedure for a compacted test response signature to provide very time-efficient off-line routines to safely recover failure data from the compacted test response signatures.

According to various implementations of the invention, an integrated circuit with embedded memory and a memory BIST controller also includes a linear feedback structure for use as a signature register that can temporally compact test response signatures from the embedded memory array during a test step of a memory test. The linear feedback structure may be, for example, a linear feedback shift register. In various implementations, the integrated circuit may also include a failing words counter, a failing column indicator, and/or a failing row indicator. The failing words counter, failing column indicator, and failing row indicator collect memory location information whenever the linear feedback structure compacts a failing test response. With these implementations, on-chip compression of diagnostic data, that is, test response data and location data, reduces the time to transfer the diagnostic data to the ATE.

According to various other implementations of the invention, a diagnostic tool receives the diagnostic data from the ATE, and selects an appropriate diagnostic technique by using a lookup table. The values stored by the failing words counter, the failing column indicator, and the failing row indicator may serve as indices for the look-up table. Moreover, the diagnostic tool may employ additional look-up tables to speed up extraction of diagnostic data from the compressed test responses. In this way, time to test and amount of test data provided to the ATE and received by the diagnostic tool from the ATE can be significantly reduced. These and other features and aspects of the invention will be apparent upon consideration of the following detailed description.

### BRIEF DESCRIPTION OF THE DRAWINGS

FIG. 1 shows an example of a memory architecture that may be used in an embedded memory;

FIG. 2 is a block diagram of an integrated circuit device including embedded memory, an MBIST controller, and components for compacting test response signatures and collecting memory location information;

FIG. 3 shows a flowchart illustrating an embodiment of a method of operation of the integrated circuit device of FIG. 2;

FIG. 4 shows a multiple input ring generator (MIRG) implemented as a signature register for the integrated circuit of FIG. 2;

FIG. 4 illustrates an example of a multiple input ring generator (MIRG) that can be employed as a signature register with various implementations;

FIG. 5 shows a ring generator-based failing words counter initialized with a 0 . . . 001 state, where the solid black color denotes the location of a logic 1 in the register;

FIG. 6 shows an implementation of a failing column indicator for the integrated circuit of FIG. 1;

FIG. 7 shows the integrated circuit device of FIG. 2 with an implementation of a failing row detector;

FIG. 8A shows an implementation of a failing row indicator;

FIG. 8B shows an implementation of an enhanced failing row indicator;

FIG. 9 shows a memory test and diagnostic environment with an enhanced failing row indicator;

FIG. 10 shows examples of diagonal cell faults in a memory array;

FIG. 11 shows an example of a faulty column in a memory array;

FIG. 12 shows an example of a faulty row and faulty column together in a memory array;

FIG. 13 illustrates injection of errors into the signature register due to failing memory cells;

FIG. 14. depicts a pre-computation phase of the discrete logarithm approach;

FIG. 15 illustrates a searching of lookup tables in the discrete logarithm approach;

FIG. 16 shows a signature register trajectory in a multiple input ring generator;

FIG. 17 illustrates a single column failure G and the reference column C₀;

FIG. 18 shows an example data structure for a fast LFSR simulation for the internal XOR LFSR implementing a characteristic polynomial x⁴+x³+1;

FIG. 19 shows an example of a fast LFSR simulation;

FIG. 20 shows an example of a two-column failure of the memory array;

FIG. 21 displays a set of linear equations corresponding to the failure of FIG. 20;

FIG. 22a and FIG. 22b show a one column and one row failure;

FIG. 23 shows a MIRG simulation used to obtain signatures for failures in neighboring cells;

FIG. 24 shows a ring generator (RG) and internal XOR LFSR producing the same m-sequence;

FIG. 25 shows a mapping between states of an LFSR and a ring generator;

FIG. 26 is a diagram showing an embodiment of a memory diagnosis flow;

FIG. 27 is a flowchart according to an embodiment of a method for diagnosing memory test failures; and

FIG. 28 shows a diagnostic tool according to an embodiment.

### DETAILED DESCRIPTION OF THE INVENTION

### Overview

As discussed in more detail below, various implementations of the invention are related to embedded memory circuit fault diagnosis in a memory BIST environment. First, a brief overview of test and diagnostic flow in a memory BIST environment is presented. Next, an embodiment of an integrated circuit device having embedded memory and a memory BIST controller with additional components to support at-speed testing is discussed, along with an embodiment of a method of operation. Various implementations of a signature register that can receive and compact test response signatures are presented. Further components, namely, a failing words counter, a failing row indicator, and a failing column indicator, are also discussed in detail, along with logic components that support the collection of memory location information and provide for on-chip compression of memory test failure data.

Following the discussion of the integrated circuit device, the embodiment of a method of operation of the disclosed integrated circuit device is discussed in more detail. This discussion shows how the aforementioned components work together in various implementations to achieve the results of continuing at-speed memory built-in self-test operations, even in the presence of multiple time related memory test failures. This discussion also shows how the components work together in various implementations to compress the diagnostic data volume, that is, test response data and location data, in order to reduce the time to transfer the diagnostic data to an automatic test equipment device.

Following that, details of an embodiment of a method of diagnosing test response signatures are presented. In particular, a look-up table of diagnostic failing test patterns will be presented, with some examples of diagnosis. The discussion also includes details of additional lookup tables and calculations to ascertain memory addresses of failing cells using a linear feedback structure. Finally, a diagnostic tool that can carry out an embodiment of a method of diagnosing test response signatures is discussed.

The embodiments of electronic circuit testing techniques and associated apparatus disclosed below are representative and should not be construed as limiting in any way. Instead, the present disclosure is directed toward all novel and nonobvious features and aspects of the various disclosed methods, apparatus, and equivalents thereof, alone and in various combinations and subcombinations with one another. The disclosed technology is not limited to any specific aspect or feature, or combination thereof, nor do the disclosed methods and apparatus require that any one or more specific advantages be present or problems be solved.

As used in this application, the singular forms “a,” “an” and “the” include the plural forms unless the context clearly dictates otherwise. Additionally, the term “includes” means “is made up of” without implying that no other elements can be present. Moreover, unless the context dictates otherwise, the term “coupled” means electrically or electromagnetically connected or linked and includes both direct connections and indirect connections through one or more intermediate elements not affecting the intended operation of the circuit.

Although the operations of some of the disclosed methods and apparatus are described in a particular sequential order for convenient presentation, it should be understood that this description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods and apparatus can be used in conjunction with other methods and apparatus. Additionally, the description sometimes uses terms like “determine” and “select” to describe the disclosed methods. These terms are high-level abstractions of the actual operations that are performed. The actual operations that correspond to these terms will vary depending on the particular implementation, but are readily discernible by one of ordinary skill in the art.

Various embodiments of the invention can be implemented in, for example, a wide variety of integrated circuits having embedded memories (for example, application-specific integrated circuits (ASICs) (including mixed-signals ASICs), systems-on-a-chip (SoCs), or programmable logic devices (PLDs) such as field programmable gate arrays (FPGAs)).

Further, any of the disclosed devices can be stored as circuit design information on one or more computer-readable media. For example, one or more data structures containing design information (for example, a netlist, HDL file, or GDSII file) can be created (or updated) and stored to include design information describing any of the disclosed apparatus. Such data structures can be created (or updated) and stored at a local computer or over a network (for example, by a server computer). Such computer readable media are considered to be within the scope of the disclosed technologies.

In addition, one or more aspects of the invention may be embodied by the execution of software instructions on a programmable computing device to perform one or more functions according to the invention. Alternately or additionally, one or more aspects of the invention may be embodied by computer-executable software instructions stored on a computer-readable medium for performing one or more functions according to the invention.

Moreover, any of the disclosed methods can be used in a computer simulation or other EDA environment, wherein test patterns, test responses, and diagnostic results are determined by or otherwise analyzed using representations of circuits, which are stored on one or more computer-readable media. For presentation purposes, however, the present disclosure sometimes refers to a representation of a circuit or a circuit component by its physical counterpart (for example, memory array, counter, register, logic gate, or other such term). It should be understood, however, that any reference in the disclosure to a physical component includes representations of such circuit components as are used in simulation or other such EDA environments.

### Diagnostic Flow

In a representative memory test and diagnostic flow, a comprehensive test, sometimes referred to as a “march” test, is typically used to check a memory array for defects. A march test is a sequence of test steps applied to each memory address in turn. Each test step typically consists of at least one write and/or read operation. In a description of a march test, as shown, for example, in the top line of Table 1, each test step is denoted by an expression in parentheses that specifies the operations performed in the test step. Each test step is separated by a semicolon from its successor. Moreover, in the expression of a test step, an arrow specifies the order in which memory is accessed in the test step. A test step may access memory in order of ascending addresses, denoted by an upward arrow [symbol] , or in order of descending addresses, denoted by a downward arrow [symbol] .

The march test of Table 1 consists of an initialization step, denoted [symbol] (w0), in which a “data background” word, denoted by “0,” is written to each memory word address in ascending order. The data background word may be a bit pattern consisting entirely of zeroes, entirely of ones, or may be some combination of both, for example, 00110011 for a particular 8-bit word. Conversely, a “1” signifies an inverse from the data background pattern, for example, a word consisting entirely of ones when the data background word consists entirely of zeroes, or in the other example above, consisting of 11001100 when the data background word is 00110011. For definiteness, in the following discussion, unless otherwise specified the data background word is a bit pattern consisting entirely of B zeroes, and the inverse word from the data background word is a bit pattern consisting entirely of B ones. Accordingly, the quotation marks around 0 and 1 are omitted below.

The initialization step is followed by a test step, [symbol] (r0, w1), in which a target memory is accessed in ascending address order. In the test step, two operations are performed in sequence on each memory address. In the first operation, (r0), a memory word is read. The 0 following the r indicates that the correct test response is the data background word, that is, 000 . . . 0, and any other response is an incorrect response. In the second operation (w1), the inverse word, that is, 111 . . . 1, is written to the memory word. Both of these operations are performed at a particular address before the test step advances to the next memory address.

In the subsequent test step, [symbol] (r1, w0), the target memory is again accessed in ascending address order. In this test step, two operations are performed in sequence on each memory address. In the first operation, (r1), a memory word is read. The 1 following the r indicates that the correct test response is the inverse word from the data background word, that is, 111 . . . 1, and any other response is an incorrect response. In the second operation (w0), the data background word, 000 . . . 0, is written to the memory word. Both of these operations are performed at a particular address before the test step advances to the next memory address.

The fourth test step, [symbol] (r0, w1), differs from the second test step, [symbol] (r0, w1), only in the order of memory access, in that the target memory is accessed in descending address order. Similarly, the fifth test step, [symbol] (r1, w0), differs from the third test step, [symbol] (r1, w0), only in that here too, the target memory is addressed in descending order.

TABLE 1
Fault dictionary for March test IFA9N

| Type | [symbol] (w0); | [symbol] (r0, | w1); | [symbol] (r1, | w0); | [symbol] (r0, | w1); | [symbol] (r1, | w0) |
|---|---|---|---|---|---|---|---|---|---|
| SAF0 | 0 | 0 | 0 | 1 | 0 | 0 | 0 | 1 | 0 |
| SAF1 | 0 | 1 | 0 | 0 | 0 | 1 | 0 | 0 | 0 |
| TF0 | 0 | 0 | 0 | 0 | 0 | 1 | 0 | 0 | 0 |
| TF1 | 0 | 0 | 0 | 1 | 0 | 0 | 0 | 1 | 0 |
| CFin0 | 0 | 0 | 0 | 1 | 0 | 0 | 0 | 0 | 0 |
| CFin1 | 0 | 0 | 0 | 0 | 0 | 1 | 0 | 1 | 0 |
| CFin2 | 0 | 1 | 0 | 0 | 0 | 0 | 0 | 1 | 0 |
| CFin3 | 0 | 0 | 0 | 1 | 0 | 1 | 0 | 0 | 0 |
| CFst0 | 0 | 0 | 0 | 1 | 0 | 0 | 0 | 0 | 0 |
| CFst1 | 0 | 0 | 0 | 0 | 0 | 0 | 0 | 1 | 0 |
| CFst2 | 0 | 0 | 0 | 0 | 0 | 1 | 0 | 0 | 0 |
| CFst3 | 0 | 1 | 0 | 0 | 0 | 0 | 0 | 0 | 0 |
| CFst4 | 0 | 0 | 0 | 0 | 0 | 0 | 0 | 1 | 0 |
| CFst5 | 0 | 0 | 0 | 1 | 0 | 0 | 0 | 0 | 0 |
| CFst6 | 0 | 1 | 0 | 0 | 0 | 0 | 0 | 0 | 0 |
| CFst7 | 0 | 0 | 0 | 0 | 0 | 1 | 0 | 0 | 0 |
| CFid0 | 0 | 0 | 0 | 1 | 0 | 0 | 0 | 0 | 0 |
| CFid1 | 0 | 0 | 0 | 0 | 0 | 0 | 0 | 1 | 0 |
| CFid2 | 0 | 0 | 0 | 0 | 0 | 0 | 0 | 0 | 0 |
| CFid3 | 0 | 0 | 0 | 0 | 0 | 1 | 0 | 0 | 0 |
| CFid4 | 0 | 0 | 0 | 0 | 0 | 0 | 0 | 1 | 0 |
| CFid5 | 0 | 0 | 0 | 1 | 0 | 0 | 0 | 0 | 0 |
| CFid6 | 0 | 1 | 0 | 0 | 0 | 0 | 0 | 0 | 0 |
| CFid7 | 0 | 0 | 0 | 0 | 0 | 1 | 0 | 0 | 0 |
| SOF0 | 0 | 1 | 0 | 1 | 0 | 0 | 0 | 0 | 0 |
| SOF1 | 0 | 0 | 0 | 0 | 0 | 0 | 0 | 0 | 0 |
| SOF2 | 0 | 0 | 0 | 0 | 0 | 1 | 0 | 1 | 0 |
| AF0 | 0 | 1 | 0 | 1 | 0 | 0 | 0 | 0 | 0 |
| AF1 | 0 | 0 | 0 | 0 | 0 | 1 | 0 | 1 | 0 |

March tests can be used to detect a variety of types of failures in memory arrays. Table 1 is a fault dictionary which correlates errors that may be observed by the march test with possible causes for the observed errors.

In general, a fault dictionary is a table in which the rows are labeled by faults, and the columns are labeled by operations of test steps. The table contains a 1 in a table cell corresponding to a particular fault and a particular test step operation if the test step operation detects the fault. Otherwise, if the test step operation does not detect the fault, the table cell contains a 0. For example, the columns under the write operations in Table 1 are filled with 0s since a write operation does not detect faults.

A fault dictionary can be created based, for example, on an analysis of the memory circuit, on simulation, or on experiment. The faults listed in the first column of Table 1 include, for example, a “stuck-at-0” fault, SAF0, and a “stuck-at-1” fault, SAF1. TF0 and TF1 are transition faults, and faults whose denotations begin with CF are coupling faults. Faults denoted SOF0, SOF1, and SOF2 are stuck-open faults. The AF0 and AF1 faults are address decoder faults. Thus, for example, SAF0 may be diagnosed when, in a test step, after 111 . . . 1 is written to a word address, any bit pattern that includes a 0 is read from that word address.

One application of memory failure diagnosis is the construction of two-dimensional pictures (bitmaps) corresponding to a memory array. The construction process uses memory test responses to select a value for each bitmap pixel, so that each pixel represents the status (that is, good or failing) of one memory cell. In monochrome bitmaps, white pixels indicate good cells while black pixels indicate failing sites of a memory array. These bitmaps naturally abstract from specific classes of fault types, for example, stuck-at faults, providing only the basic information of whether a cell was good or not given a read operation.

Color bitmaps, on the other hand, can have different pixel colors representing different classes of faults. For example, stuck-at faults may be represented by one color, and transition faults by a different color. A color bitmap can be obtained, for example, after applying a suite of march tests, with different test steps and/or data backgrounds in each march test, in a BIST mode. Color bitmaps can in addition or alternatively be obtained during off-line post processing of a set of monochrome bitmaps representing the same copy of a memory array. In certain embodiments, a fault dictionary can be used (see, e.g., Table 1) to help in creating color error bitmaps of memory arrays. Such a dictionary summarizes the results of a reasoning process which is based on a specific march test routine. Examples of dictionaries and dictionary generation methods as may be used with the disclosed technology are described in L.-T. Wang, C.-W. Wu, X. Wen, “VLSI Test Principles and Architectures. Design for Testability,” Morgan Kaufmann Publishers, New York, 2006. It should be understood that memory tests other than march tests can be applied in a memory BIST environment, for example, Galpat, Walking, Butterfly, Sliding diagonal, NPSF, and other tests. There are hundreds of variations of algorithms that have been proposed. Testing algorithms are described in A. J. van de Goor, “Testing Semiconductor Memories: Theory and Practice,” John Wiley & Sons Inc., New York, 1998, and in R. Dean Adams, “High Performance Memory Testing: Design Principles, Fault Modeling, and Self-test,” Springer, N.Y., 2002. It should be understood that use of the methods and devices described herein with memory tests other than march tests is within the scope of this disclosure.

Integrated Circuit Device with Temporal Compaction

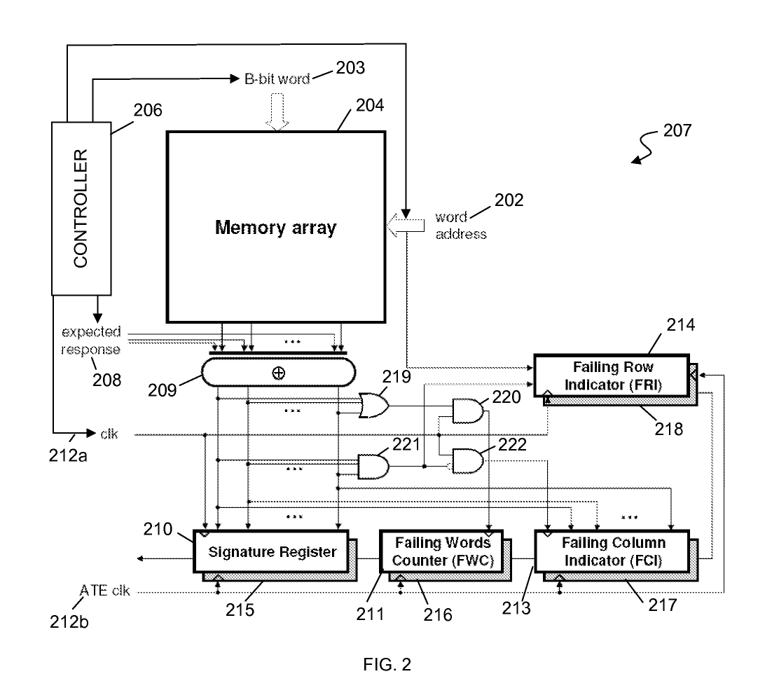

In various embodiments, fault diagnosis can produce very accurate monochrome error bitmaps that show the failing memory cells. For example, FIG. 2 is a block diagram of an integrated circuit device 207 including an embedded memory array 204, an MBIST controller 206, and components 210, 211, 213, and 214 for compacting test response signatures and collecting memory location information. Component 210 is a signature register and is discussed in detail below. Components 211, 213, and 214 are a failing words counter (FWC), a failing column indicator (FCI), and a failing row indicator (FRI), respectively, and are also discussed in detail below. The FWC 211, the FCI 213, and the FRI 214 may be referred to herein as location data collectors. The signature register 210 and the location data collectors 211, 213, and 214 in addition may be referred to herein as test data collectors or as registers. A detailed description of the new hardware's functionality, as well as certain extensions of this architecture, is presented below.

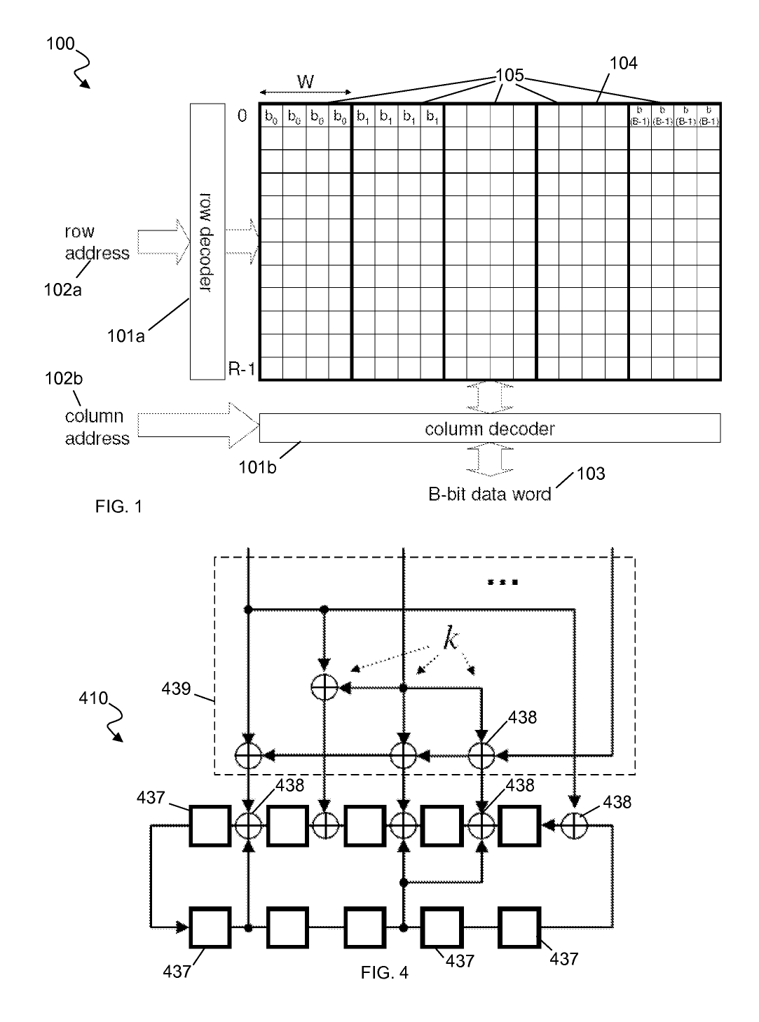

While a particular example of an integrated circuit device 207 with only a single embedded memory array 204 and a single MBIST controller 206 is discussed below, it will be appreciated that the integrated circuit device 207 can have multiple embedded memories, and can have multiple memory BIST controllers so that each of the memory BIST controllers can test several embedded memories. The embedded memory array 204 may have a memory architecture such as that shown above in FIG. 1. Memory cells in a memory array may be addressed in either a fast column or a fast row addressing mode. In a fast column addressing mode, consecutive words in a column are addressed before going on to the next column. In a fast row addressing mode, consecutive words in a row are addressed before going on to the next row. For the sake of the presentation, it is assumed that the memory array 204 is addressed in the fast column mode, and that bits are interleaved in the memory words. Nevertheless, embodiments of the procedures discussed herein can be easily extended to other memory organizations.

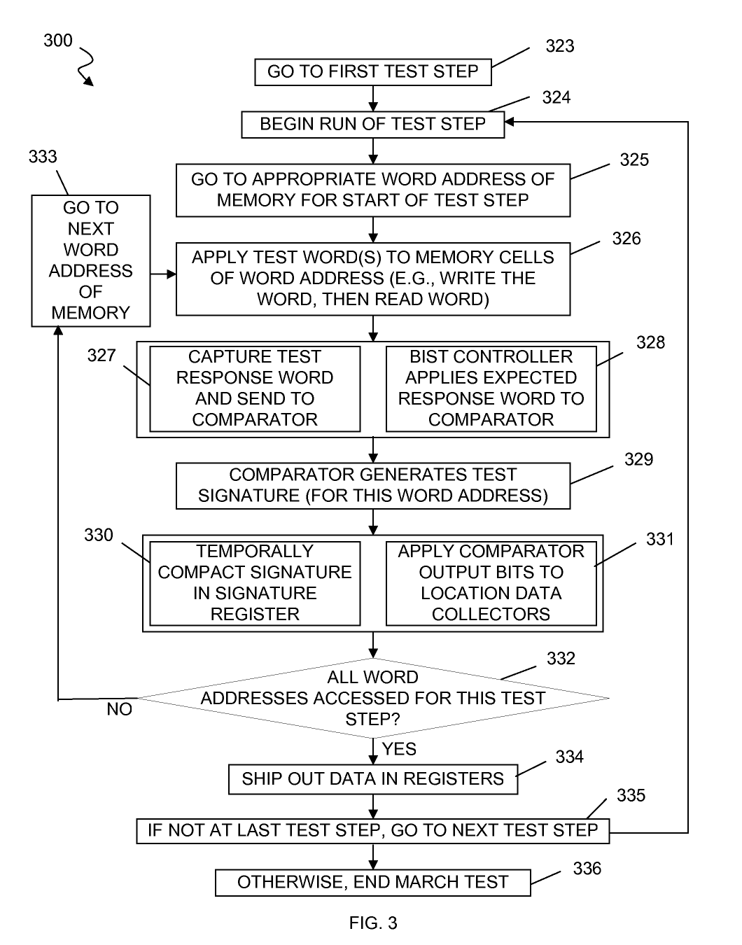

FIG. 3 shows a flowchart 300 illustrating an embodiment of a method of operation of the integrated circuit device 207 (see FIG. 2). Steps of the method 300 are discussed together with a more detailed description of the integrated circuit device 207. In this example, the memory BIST controller 206 is configured to apply a particular march test and a particular data background word. The memory BIST controller 206 generates a test pattern word 203 to apply to the memory array, and generates a clock signal 212a to synchronize operations of the on-chip test hardware. The method 300 may be initiated in response to a signal from an automatic test equipment device. Moreover, individual steps of the method 300 may be performed in response to a signal from the memory BIST controller 206, or in response to a clock signal 212b from the ATE device.

In an initialization step 323, the method begins at the first test step, for example, of a march test such as the march test shown in the top line of Table 1. The memory BIST controller 206 (see FIG. 2) begins 324 execution of the test step. When beginning the test step, the controller 206 selects 325 the appropriate word address 202 of the memory array 204 for the start of the test step. For example, if the test step requires words of the memory array 204 to be addressed in order of ascending address, the appropriate beginning word address is the lowest word address of the memory array. Conversely, if the test step is to address the words of the memory array 204 in descending order, the appropriate beginning word address is the highest word address of the memory array.

The BIST controller 206 (see FIG. 2) applies 326 a test word 203 to the memory cells of the word address. As discussed above, a test word can be a “data background,” for example, a word consisting entirely of 0s, or some other predefined word; or, a test word can be the inverse of the data background, that is, for example, a word consisting entirely of is when the data background is a word consisting entirely of 0s. Moreover, in applying a test word to the memory address, several operations may be executed, and in some cases more than one test word may be applied, or the same test word may be applied in multiple operations. For example, in the second test step of Table 1, first a read operation is carried out, in which a correct test response is a 0, then at the same word address, a write-1 operation is performed. In other types of test steps, multiple reads and/or multiple writes to the same memory address may be performed.

When a read operation is carried out, a test response word may be captured 327. Concurrently, the memory BIST controller 206 (see FIG. 2) may generate or make available an expected test response word 208, to be applied 328 to a comparator 209 along with the captured test response word. That is, one or more test response words (e.g., every test response word) are compared against the expected response word by using, for example, the comparator 209. In various embodiments, the comparator 209 is a combinational logic network, such as, for example, an XOR or XNOR network. The comparator 209 identifies a bit position in which a test response word differs from an expected response word. For example, if the expected response word is 11111111, and the observed test response word is 11011111, the comparator output is 00100000. Thus the comparator 209 generates a test signature for the currently accessed word address. It is to be noted that following each read operation, the comparator 209 generates 329 a test signature before the next word address is accessed. A test response signature generated by the comparator 209 as just described may also be referred to in this disclosure as an error vector.

Following operation 329 of the comparator 209 (see FIG. 2) to generate a test signature, the signature is temporally compacted 330 and stored in the signature register 210. In various embodiments, the temporal compaction 330 employs sequential logic in for example, a multiple input ring generator (MIRG), to sequentially store signatures encoded as states of the ring generator. (To maintain continuity of the discussion of the method 300, details of the MIRG are provided below.) In various embodiments, the comparator 209 output bits are applied 331 to the location data collectors, for example the FWC 211 and the FCI 213. The method step 331 may be performed concurrently with the temporal compaction 330. In addition, if proper conditions are met, as discussed below, a B-input AND gate 221 may function as a failing row detector and may assert a logical one to the FRI 214.

Thus, a resultant difference shown by the output of the comparator 209 (see FIG. 2) drives the four test data collectors 210, 211, 213, and 214, which are configured to work continuously during at-speed testing. It should be understood that in various embodiments another error pattern rather than the resultant difference provided by the comparator 209 may drive the four test data collectors 210, 211, 213, and 214. For example, since the test pattern word itself is known (as part of the specification of the march test, for example), in various embodiments the test response word may be directly captured in the signature register for use in a subsequent diagnostic analysis. In these latter various embodiments, an on-chip comparator can be omitted.

Following step 331, the BIST controller 206 (see FIG. 2) can determine 332 whether all the word addresses of the memory array have been accessed for this test step. If word addresses remain to be tested for this test step, the next word address to be tested is selected 333, and the method can return to step 326. If all the word addresses have been accessed for this test step, then the compacted signature data can be transferred 334 from the signature register 210. In various embodiments, the data collected in the FWC 211, the FCI 213, and the FRI 214 are transferred concurrently with the transfer of the compacted signature data. In various embodiments, the transfers may be to an ATE device. In this way, the test data collectors 210, 211, 213, and 214 experience periodic downloads of their content, for example, at the end of every test step. The test data collectors 210, 211, 213, and 214 allow test response data to be continuously collected at-speed during a test step.

In various embodiments, the transfer 334 of test data may be facilitated by the use of “shadow registers.” In the embodiment illustrated in FIG. 2, each of the test data collectors 210, 211, 213, and 214 has an associated shadow register, 215, 216, 217, and 218, respectively. It should be understood that in various other embodiments shadow registers may be absent. Once a single test step is completed, the content of the test data collectors is either downloaded to the ATE as just mentioned or, if shadow registers are present, loaded into the corresponding shadow registers 215, 216, 217, and 218. That is, in method step 334, test data may be either downloaded to the ATE, or may be loaded into the corresponding shadow registers.

In various embodiments in which shadow registers are used, the test data collectors 210, 211, 213, and 214 (see FIG. 2) continue collecting test response and location data at-speed, for example, for a successive test step, while the shadow registers 215, 216, 217, and 218 are unloaded at the sampling rates acceptable by an external ATE. The unloading of the shadow registers 215, 216, 217, and 218 may be controlled by an independent clock signal 212b from the ATE. It is worth noting in this example approach that no extra breaks of test steps are required in order to dump or to download test data. In another step of the method 300, the controller 206 can determine if the march test has finished the final test step, and if not, the testing advances to the next test step 335, and then back to method step 324. Otherwise the march test ends 336.

Continuing with the discussion of various components of FIG. 2 in more detail, the signature register 210 is used to collect all test responses and produce the actual temporally compacted error signature. In various embodiments, the signature register 210 works in a continuous manner starting with an initial state. It should be understood that in various embodiments the initial state is the state in which all bits of the signature register hold zeroes. In various other embodiments an initial state may be used in which at least one bit of the signature register is non-zero. It is assumed in the remainder of this disclosure that the signature register is initialized to a non-zero state.

In the initial state, therefore, the signature register's contents are in a specified non-zero state, signifying that no errors have been compacted. It should be understood that any “seed” other than zero can be loaded into the signature register to establish an initial state. The signature register employs sequential logic—rather than only combinational logic—so that test response signatures output by the comparator 209 presented to the signature register by the outputs of the comparator are sequentially stored in states of the signature register 210, that is, temporally compacted. The content of the signature register 210 is periodically unloaded—for example, once per test step—so that errors detected in a test step can be identified and diagnosed. The content of the signature register 210 indicates whether failures in the memory array were detected.

In some embodiments, the signature register 210 (see FIG. 2) may be implemented by using a multiple input ring generator (MIRG) driven by outputs of the test response comparator 209. A ring generator is a linear finite state machine with reduced internal fanout and reduced levels of logic, often obtained by applying particular transformations to a “canonical” linear finite state machine such as a linear feedback shift register. A canonical linear feedback shift register is one that satisfies specific performance and architecture requirements. A MIRG can provide speed and other advantages over a canonical linear feedback shift register. FIG. 4 illustrates an example of a MIRG 410 that can be employed as a signature register with various implementations of the invention. Latches 437 are interconnected so that the output of one latch is provided as input to another latch, and/or as input to a logic network, for example any of the logic networks 438. Any of the logic networks 438 may be, for example, an XOR or XNOR network, and need not be identical logic networks.

Some of the latches 438 in the MIRG are connected so as to receive input from a logic network (XOR or XNOR, for example) rather than directly from another latch, in order to implement performance identical to the associated “canonical” linear feedback shift register. In addition, some of the XOR or XNOR networks 438 are configured as an “injector” network 439. An injector operates to receive input external to the MIRG, or to provide output from the MIRG. In FIG. 4, the injector network 439 operates to receive input from the comparator 209 (see FIG. 2). Examples of ring generators that can be used in the disclosed embodiments are further described in G. Mrugalski, J. Rajski, J. Tyszer, “Ring generators—New devices for embedded deterministic test,” IEEE Trans. on CAD, Vol. 23, No. 9, September 2004, pp. 1306-1453, which is hereby incorporated herein by reference in its entirety.

Continuing with discussion of the integrated circuit device 207 (see FIG. 2), a failing words counter (FWC) 211 may be used in some implementations to count the number of incorrect test response words. Two gates, a B-input OR gate 219 and an AND gate 220, placed in sequence between the comparator 209 and FWC 211, can be used to gate the clock line 212a so that the FWC 211 is triggered only when at least one error propagates from the comparator's output. Once an entire test step is completed, the FWC 211 provides very accurate information regarding quantity of failing memory words.

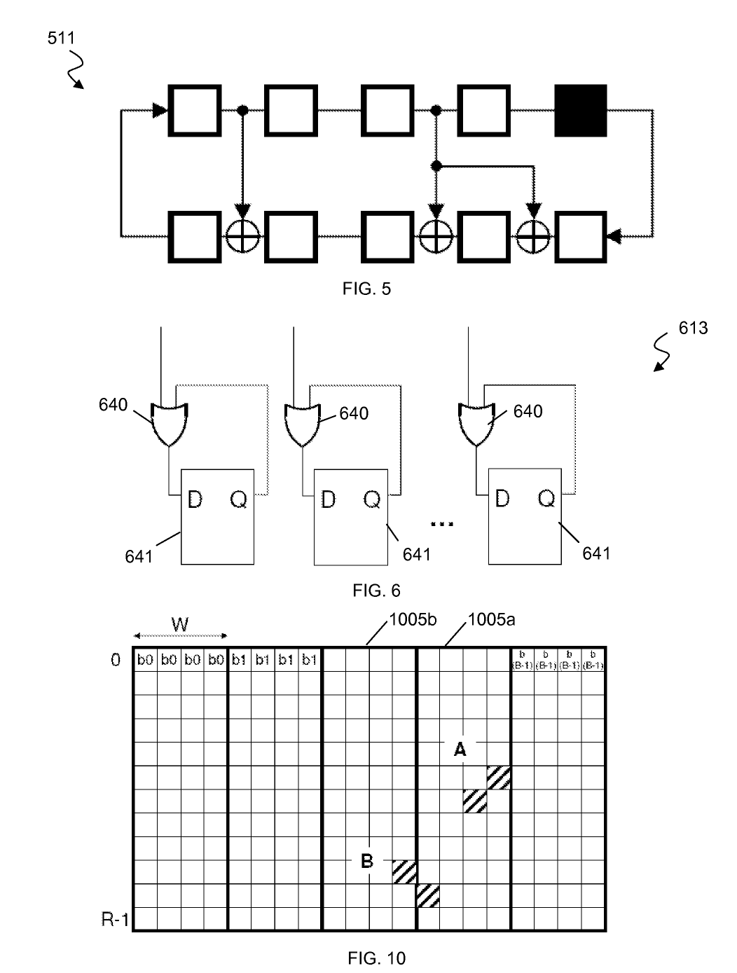

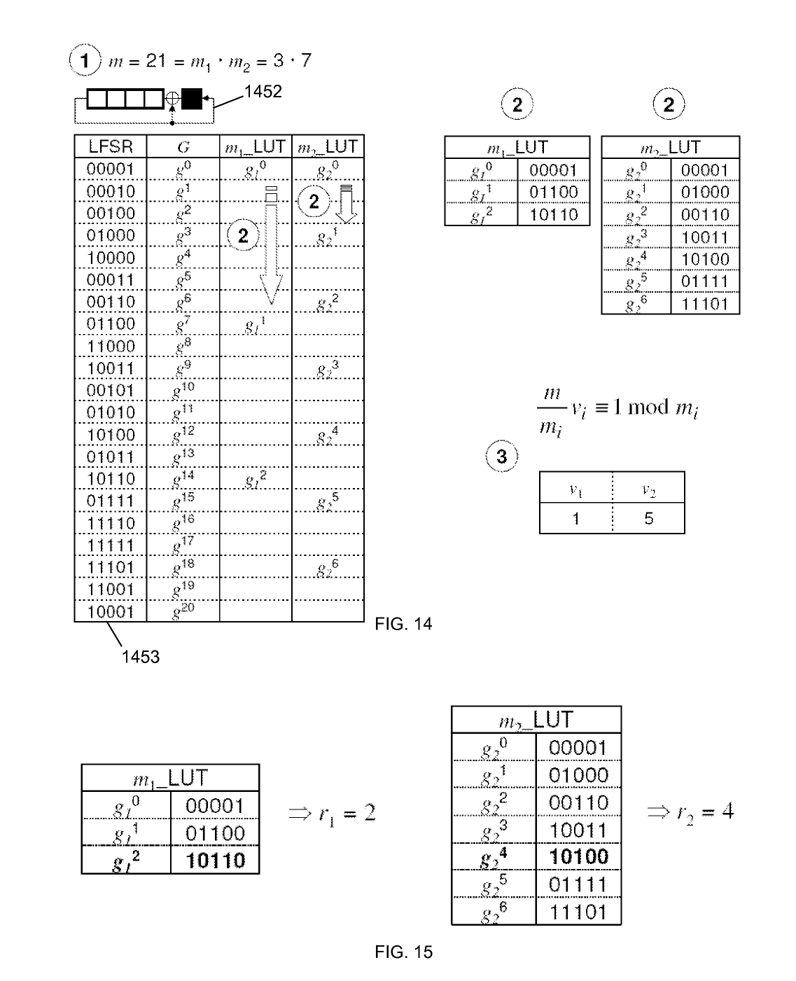

In general, any counting device can be used to act as the FWC 211 (see FIG. 2). Because of timing constraints, however, linear feedback shift registers (LFSRs) can be employed as efficient event counters in which the increment function is implemented by just a single shift of the register. In particular, a ring generator can operate at higher speeds than conventional event counters and canonical LFSRs. FIG. 5 shows a ring generator-based failing words counter 511 initialized with a 0 . . . 001 state, where the solid black color denotes the location of a logic 1 in the register The significantly reduced number of levels of XOR logic, minimized internal fan-outs, and simplified circuit layout and routing of a ring generator, as compared to canonical forms of LFSRs, enables the higher operational speed. Therefore, in certain embodiments of the disclosed technology, a small ring generator 511 is employed to count incorrect test response words. In some cases, this circuit is operated in a particular manner in order to enable its counting functionality. Further details of ring generator operation are discussed below in connection with FIG. 14 and FIG. 24.

As shown in the embodiment of FIG. 2, the integrated circuit device 207 also includes a failing column indicator (FCI) 213. The failing column indicator 213 stores locations of the failing output bits throughout a single test step, except in the case where the errors affect all the outputs of the comparator 209. The latter case can be handled by the two AND gates 221 and 222 placed between the outputs of the comparator 209 and the clock input of the FCI 213.

In some embodiments, the content of the FCI 213 (see FIG. 2) is downloaded each time a test step is finished. When tracing single cell/column-like failing patterns, the FCI 213 can indicate vertical memory segments that should be considered as failing cells. Furthermore, the FCI 213 reduces the time necessary to identify the exact fault locations.

FIG. 6 shows an implementation 613 of a failing column indicator (FCI). The FCI 613 includes B OR gates 640, one for each bit of a test response word. One input of each OR gate 640 receives a test response signature bit from the comparator 209 (see FIG. 2). The output of an OR gate 640 is input to a D flip-flop 641. The D flip-flop output is returned to the OR gate 640 as the OR gate's second input. In this way, the FCI 613 acts accumulatively, that is, once a particular column is identified as having a failure, the FCI 613 retains a value signifying an error in that column, until the end of the test step.

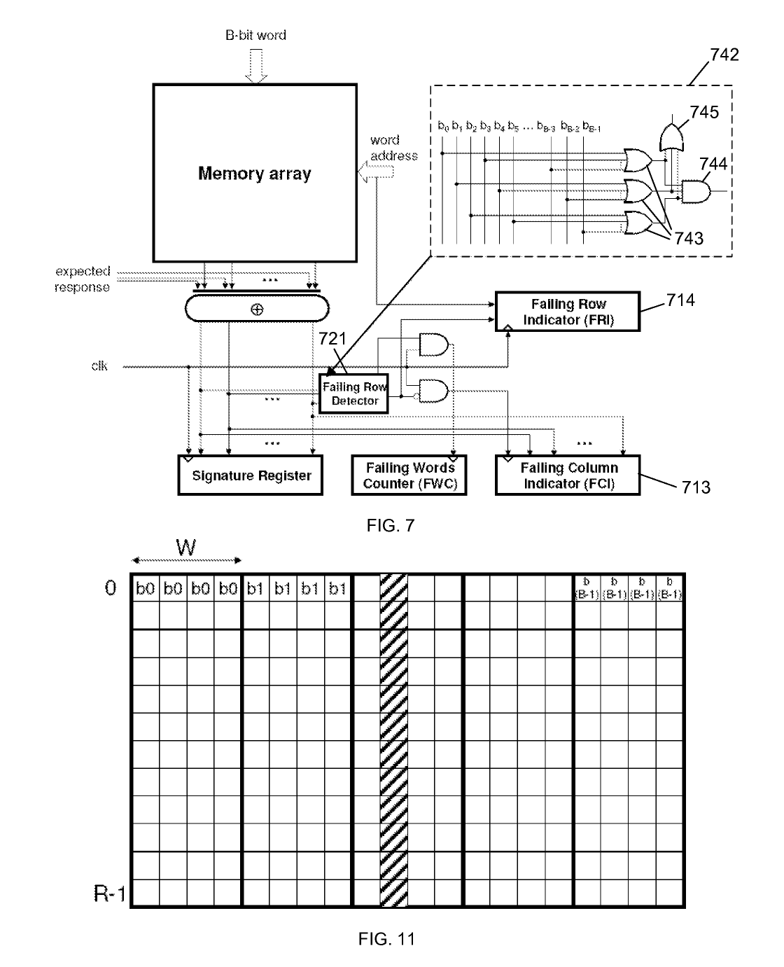

Returning to FIG. 2, clocking of the FCI 213 typically depends on detection of particular failing patterns. For errors involving all cells belonging to the same row, it suffices to use only a single B-input AND gate 221 to detect a row failure and to prevent the FCI 213 from asserting all of its bits, as shown in FIG. 2. However, detection and recording of errors forming partial-row failures is more complex and requires a failing row detector, as illustrated in FIG. 7. Although a memory BIST controller is not shown in the circuit of FIG. 7, it should be understood that the embodiment of FIG. 7 also includes a BIST controller similarly configured as the controller 206 of FIG. 2.

The circuit of FIG. 7 enables all partial-row failures extending over at least three adjacent vertical segments to be detected, but not recorded by the FCI 713. The failing row detector 721 is enlarged in the diagram 742. As shown, the failing row detector 721 includes three OR gates 743. Whenever three consecutive bits show failures, all three of the OR gates 743 show logical one at their outputs. In this case, the AND gate 744 also shows a logical one at its output indicating a failing row has been detected (where now a failing row means three or more bits in the row have failures). At the same time, any single failure of a bit is passed on by one of the OR gates 743 to the OR gate 745, and thereby passed on to the output of OR gate 745. Thus, the failing row detector 721 of FIG. 7 replaces the gates 219 and 221 of FIG. 2, and implements a less stringent definition of a “failing row”. As a result, such failing rows will not be mistakenly treated as multiple column failures.

As mentioned previously, various embodiments of the disclosed technology include a failing row indicator (FRI) 214 that can act as a complement to the FCI 213. Various other embodiments may include a FRI 714 to complement the FCI 713 mentioned above. In various embodiments that include a FRI 714, the FRI stores information related to errors occurring in rows.

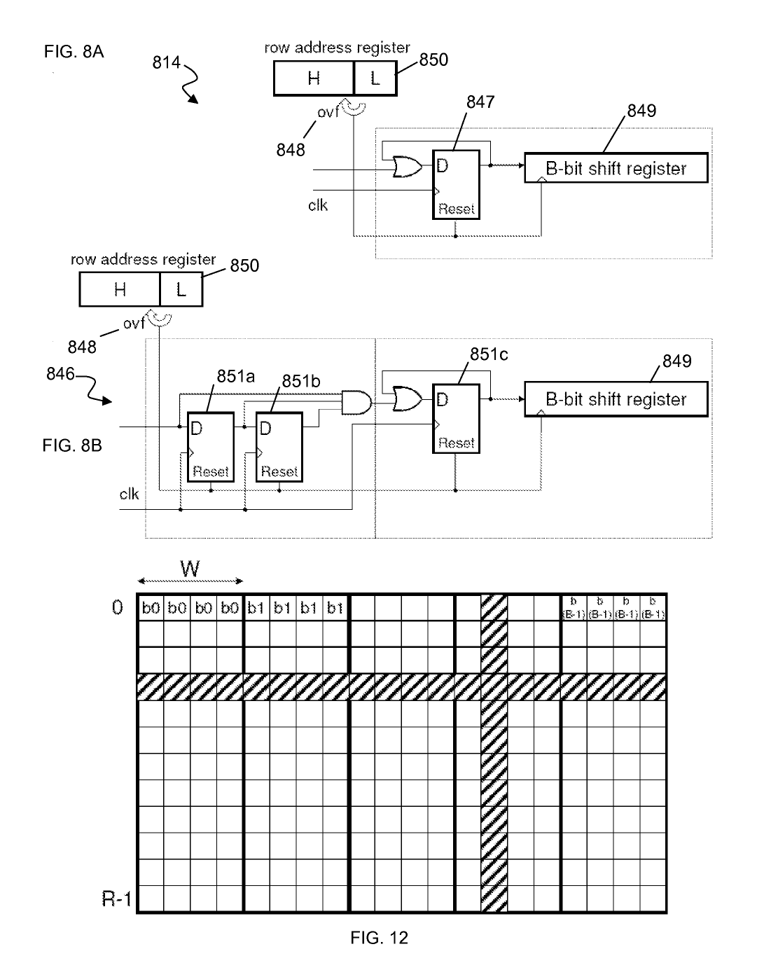

FIG. 8A shows one form of a failing row indicator 814, in which a flip-flop 847 receives a logical one from failing row detector 721 of FIG. 7, or alternatively the AND gate 221 of FIG. 2, and retains the logical one until it is moved to the FRI shift register 849. Thus, the failing row indicator 814 tracks which rows were detected to be a failing row, and which ones were not. The shift register 849 is an at least R-bit shift register, one bit for each row of the memory array 204 (see FIG. 2). Typically, B>R, so a B-bit shift register may be used, as shown.

Bits stored in the shift register 849 are advanced along the register when testing in a test step advances to another row. Clocking of the shift register 849 when testing of the words in a row is completed is accomplished by detecting an overflow (ovf, 848) in the row address register 850. For example, suppose each row consists of four words. The first word may have an address of, for example, 00000000. The next word may have an address of 00000001. The third and fourth words have addresses of 00000010 and 00000011, respectively. After that, incrementing the address register to advance to the next word address is memory gives an address of 00000100. That is, incrementing the lowest two bits of the address register has produced an overflow (of those two bits), as the memory address advances to the next row. This overflow occurs every time the address register 850 advances from an address ending in 11, to the next following address. In this way, the ovf signal 848 can trigger a reset of the flip-flop 847, and can also trigger the shift register 849, to track which row in memory is currently under test, and which rows have or have not had failures. That is, successive bits of the shift register 849 correspond uniquely to horizontal segments of the memory array 204 (see FIG. 2) comprising a certain number of rows. As a result, orthogonal information kept in both the FCI 213 and the FRI 214, can be used to isolate that part of the memory array 204 where actual failures occur.

An embodiment of an enhanced version of the failing row indicator (E-FRI) 846 is shown in FIG. 8B. The enhanced failing row indicator 846 can be used to improve recognition of row-related errors. Due to delay introduced by the two-bit register L of the row address register 850, the right-hand side flip-flop receives a logical one every time at least three errors appear at any output of the comparator 209 (see FIG. 2) in three consecutive time frames. It also enables partial-row failures not extending over three adjacent vertical segments to be detected and reported by the enhanced failing row indicator.

In more detail, the enhanced failing row indicator 846 includes a B-bit shift register 849 that is clocked whenever an overflow of the row address register 850 takes place. D flip-flops 851a, 851b, and 851c are configured to register three successive word failures in the same row. When this occurs, an output of logical one is provided by D flip-flop 851c to the shift register 849 to record the row failure when the shift register 849 is clocked by the overflow 848 of row address register 850.

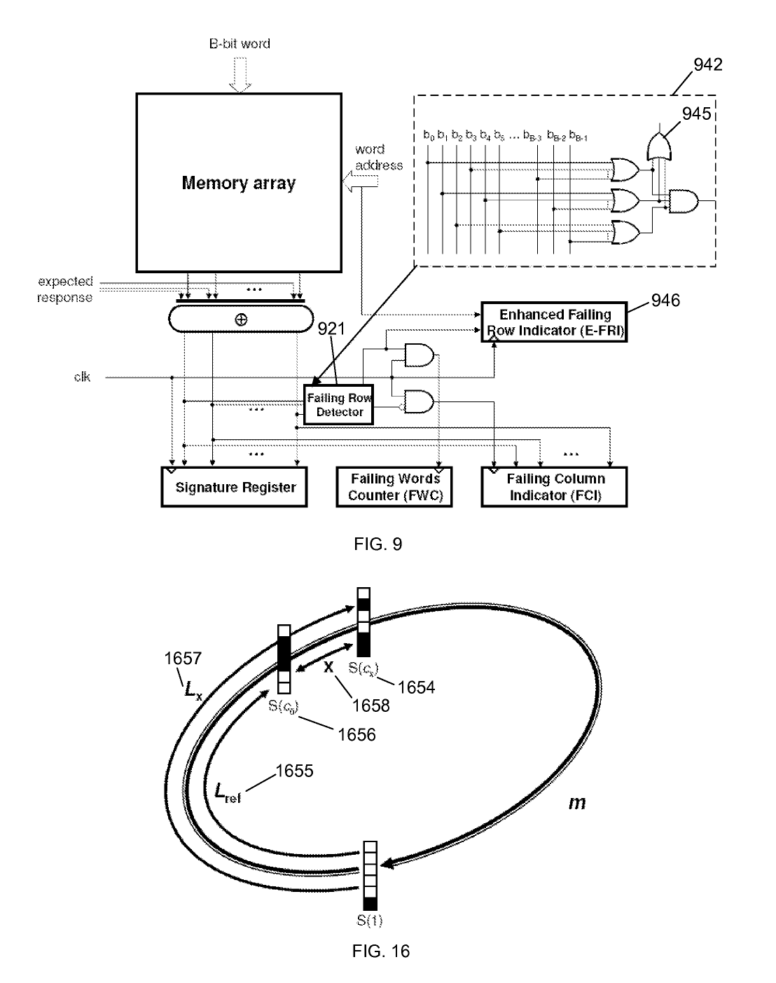

FIG. 9 illustrates application of the enhanced failing row indicator 946 similar to E_FRI 846 of FIG. 8 in a built-in self-diagnosis (BISD) environment. Although a memory BIST controller is not shown in the circuit of FIG. 9, it should be understood that the embodiment of FIG. 9 also includes a BIST controller similarly configured as the controller 206 of FIG. 2. Note that although the failing row detectors 721 (see FIGS. 7) and 921 have identical circuitry 742 and 942, the connection between failing row detector 921 and the enhanced failing row indicator 946 differs from the connection between the failing row detector 721 and the failing row indicator 714. The difference is that the enhanced failing row indicator 946 receives input from the OR gate 945 of the failing row detector 921, whereas the failing row indicator 714 receives input from the AND gate 744. It may be recalled that in the implementation of FIG. 7, the failing row detector 721 is configured to detect when three adjacent bits of the same word fail. In the implementation of FIG. 8, however, the failing row detector 921 and the enhanced failing row indicator 946 together detect three consecutive failing words in a row. Detection of three failing words in a row is again a less stringent condition for registering a failing row than the condition implemented in FIG. 2 with the AND gate 221.

Three particular embodiments of the integrated circuit device 207 (see FIG. 2) have been discussed: the embodiment show in FIG. 2 itself, the embodiment shown in FIG. 7, and the embodiment shown in FIG. 9. Each of the embodiments can support collection of compacted test signatures and memory location data for failed memory tests. In the following discussion of failing patterns and of failure diagnosis, discussion will be with reference to the embodiment shown in FIG. 9.

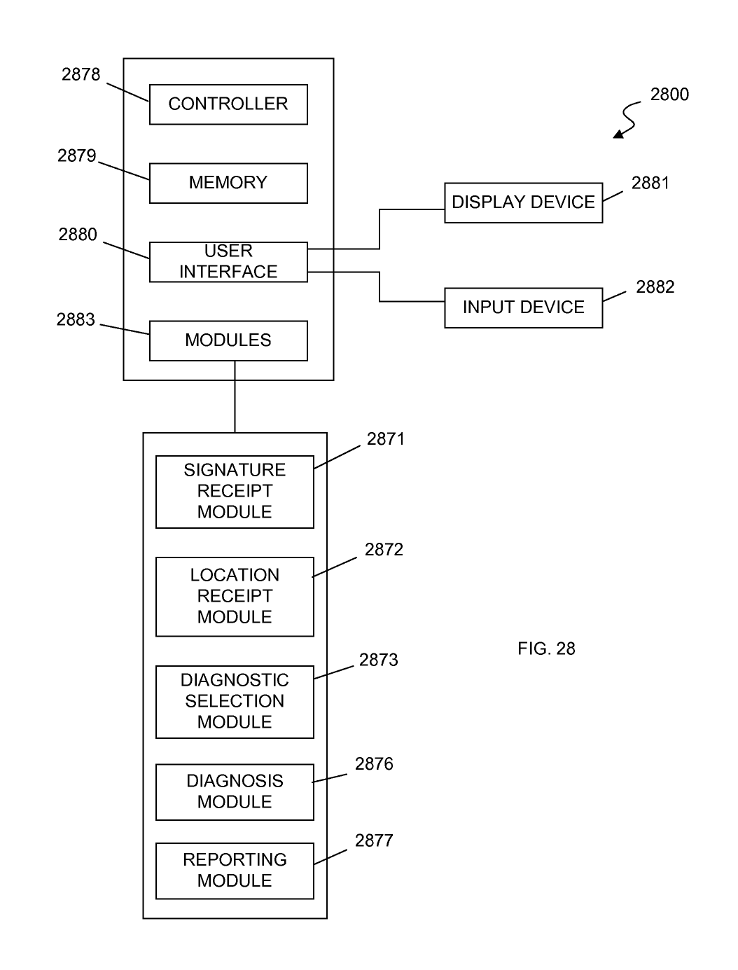

As discussed above, at the end of a test step, compacted test response signature data, and memory location data, are made available to the ATE. Subsequently, the compacted test response signature data and memory location data can be provided by the ATE to a diagnostic tool (2800, see FIG. 28). The diagnostic tool applies diagnostic procedures to the compacted signature data to determine the location of failing memory cells. The diagnostic procedures are based on an analysis of failing patterns, discussed below in connection with Table 2. The diagnostic procedures also make use of properties of linear feedback structures to enable efficient determination of location of failing memory cells as explained below. As discussed below, lookup tables may also be used to enable efficient searching for failing patterns and the locations in memory of the corresponding failing memory cells.

Turning first to the analysis of failing patterns, failing patterns can be grouped into classes that can be distinguished both by the layout of the failing pattern in the memory array, and by the values of FWC, FCI, and FRI that would be collected in the presence of these types of failing patterns. In Table 2 and the further discussion below, FWC, FCI, and FRI can refer to the values collected by the FWC 211, the FCI 213, and the FRI 214.

The rationale for collecting data in the FWC 211 (see FIG. 2), the FCI 213, and the FRI 214 is to enable efficient diagnosis of memory test failures based on the compacted test response signatures. Below, possible combinations of FCI, FRI and FWC are summarized with respect to failing pattern classes. The failing pattern classes together with corresponding contents of FCI, FRI and FWC are presented in Table 2. In addition, several examples of faults capable of producing some of the FCI/FRI/FWC combinations are set forth below.

TABLE 2
Failing pattern classes and the corresponding contents of FCI, FWC and FRI

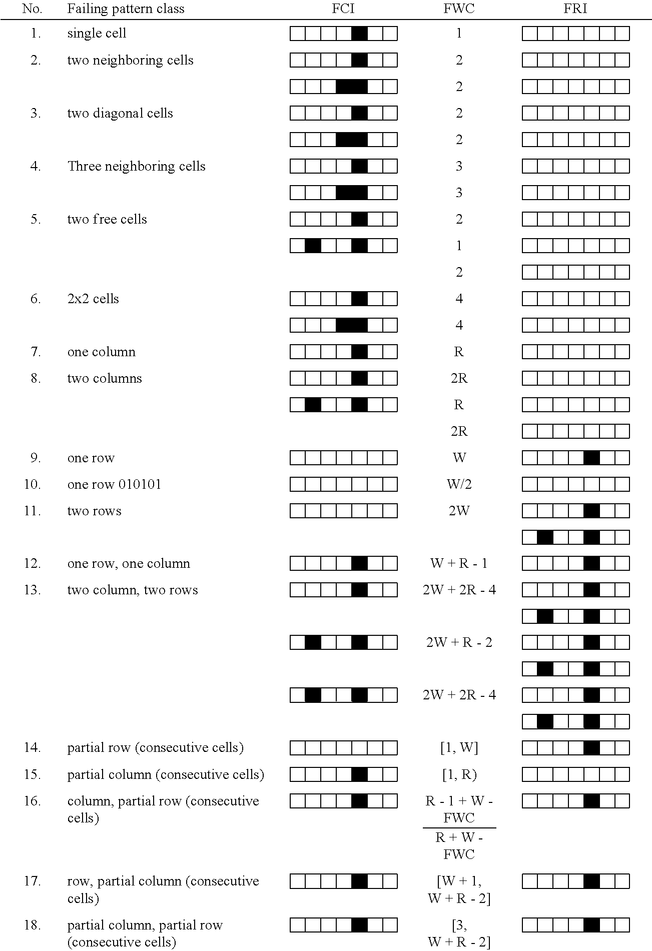

In a first example of faults whose failing pattern classes are listed in Table 2, two diagonal cells show failures. This corresponds to failing pattern class No. 3 in Table 2. There are two possible situations as shown in FIG. 10. In the figure, slashed lines in memory arrays indicate failing memory cells. In the first situation, A, both failing cells belong to the same vertical segment 1005a. Thus, the FCI 828 (see FIG. 8) indicates the errors at only one output of the comparator 822 (see the first part of row 3 in Table 2). In the second situation, B, the failing cells belong to two neighboring vertical segments 1005a and 1005b. This time, two neighboring flops of the FCI 828 indicate errors at the outputs of the comparator 822 (the second part of row 3 in Table 2). In both situations, two errors appear at the outputs of the comparator 822 in different time slots, so the value of FWC 826 is two. As no “ones” appear at any output of the comparator at any three consecutive time frames, the FRI 946 does not report any error.

In the second example, all the cells in a single column show failures. This corresponds to failing pattern class No. 7 in Table 2. An example of this situation is shown in FIG. 11. For this kind of failing pattern, all failures propagate to the same output of the comparator 822 (see FIG. 8), so only one FCI 828 flip-flop indicates an error. There are exactly R failing memory cells, and thus the value of the FWC 826 is R. Similarly to the previous example, the FRI 946 is not affected.

In the third example of faults whose failing pattern classes are listed in Table 2, all the cells in a row and a column show failures, as shown in FIG. 12. This corresponds to failing pattern class No. 12 in Table 2. For such a failing pattern, the FCI 828 (see FIG. 8) indicates only one erroneous bit since only incomplete word failures are stored in the FCI. In general, there are W completely erroneous words that affect only one FRI 946 bit. Although the number of incorrect test response words may appear to be W+R, only W+R−1 erroneous words are counted by FWC. This is because one failing cell belongs also to the failing row.

### Diagnostic Techniques

Turning now to a discussion of how failure diagnosis may be performed according to various embodiments, several diagnostic techniques can be applied in different circumstances to determine locations of failing memory cells. In this disclosure, four generic diagnostic techniques are discussed that can be used alone or in combination with one another to perform accurate fault diagnosis in the MBIST environment. It should be appreciated that these diagnostic techniques may be carried out on-chip in some embodiments. In other embodiments, the diagnostic techniques may be applied in a separate diagnostic tool external to the integrated circuit device under test. In this disclosure the diagnostic techniques are also referred to as diagnostic schemes.

Typically, the disclosed embodiments of diagnostic techniques follow at-speed test data collection as shown earlier. Depending on a memory failure type (indicated, for instance, by the content of FCI 828, FRI 946 and FWC 826 (see FIG. 8)), one of the schemes described here can be deployed to make the diagnostic process time-efficient and accurate. In the remainder of this disclosure, the following notation will be used: whenever flip-flops are shown in figures, their content is represented as black and white boxes corresponding to the logic values of 1 and 0, respectively. Similarly as in the previous discussion, slashed lines in memory arrays indicate failing memory cells.

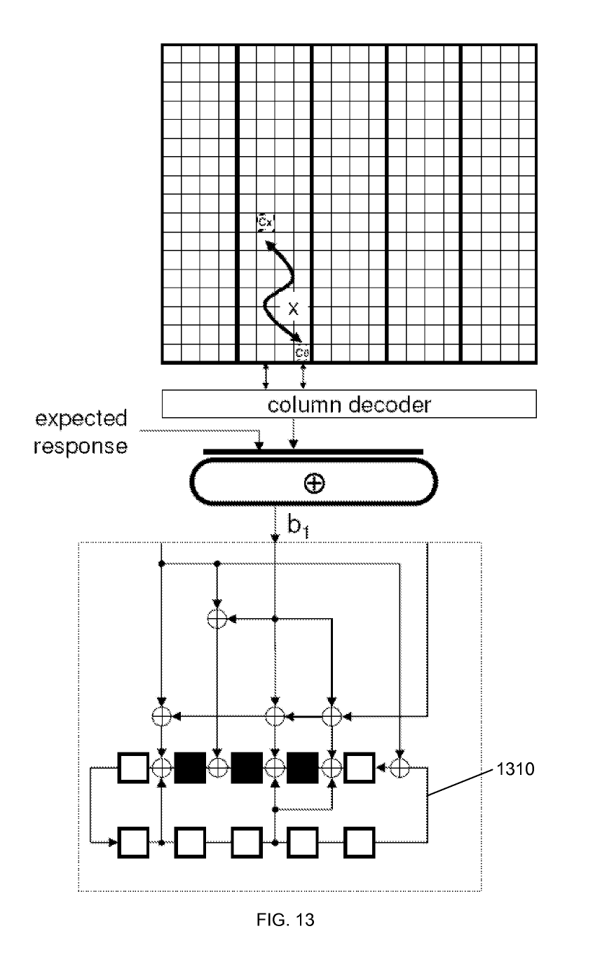

A first diagnosis technique is referred to herein as a discrete logarithm approach (DELTA), and can be used to diagnose the majority of failures occurring most commonly in memory arrays. As an example, consider a failure presented in FIG. 13, which illustrates injection of errors into a signature register 1310 due to failing memory cells. Assume that a signature produced by the failing reference cell c₀ is known and is initially stored in the signature register 1310. Moving the location of the faulty cell cₓ away from the reference cell (i.e., increasing the distance x) by one corresponds to advancing the signature register 1310 by one clock cycle. The main goal of the diagnostic procedure is now to determine the distance x between the reference cell and the faulty one. Alternatively, one has to find the number of clock cycles that have been applied to the signature register 1310 since the time an error has been recorded by the signature register. Based on the number of clock cycles, the test algorithm, and the addressing scheme, the distance x can be determined.

DELTA, the diagnostic technique presently under discussion, takes advantage of a discrete logarithm-based method. Further detail about the discrete logarithm-based method is provided in D. W. Clark, L.-J. Weng, “Maximal and near-maximal shift register sequences: efficient event counters and easy discrete logarithms,” IEEE Trans. on Computers, vol. 43, No. 5, May 1994, pp. 560-568, which is incorporated herein by reference in its entirety. The discrete logarithm-based method solves the following problem: given an internal XOR LFSR (Galois LFSR) and its particular state, determine the number of clock cycles necessary to reach that state assuming that the LFSR is initially set to 0 . . . 001. The method employs the Chinese Remainder theorem and requires pre-computing of a reasonable number of LFSR states which, once generated, can be stored in a look-up table (LUT). The number of LFSR states to be pre-computed is given by m₁+m₂+ . . . +mₖ, where the product m₁·m₂· . . . ·mₖ gives the period m of the LFSR. This period should be chosen carefully to guarantee small values of the coefficients mᵢ (each period has different factorization). The pre-computations can be efficiently done using the fast LFSR simulation introduced below. For example, it takes about 5 seconds on 2.4 GHz CPU to generate all required values for a 55-bit compactor.

DELTA is very time-efficient and usually works in a fixed time. The pre-computation phase is typically executed only once in the diagnostic tool. A particular embodiment of the pre-computation can be summarized by the following method acts (which can be performed alone or in various combinations and subcombinations with one another):
1. Find a prime factorization m₁·m₂· . . . ·mₖ of the LFSR period m—see step 1 in FIG. 14, which depicts a pre-computation phase of the discrete logarithm approach. Here k is the number of prime factors of m. For example, in FIG. 14, m=21, k=2, with m₁=3 and m₂=7.
2. For one or more periods mᵢ (e.g., for each mᵢ), generate a LUT of size mᵢ, by simulating the LFSR initialized to 0 . . . 001 (note that m/mᵢ computation steps are needed for each LUT entry—see the arrows in FIG. 14). It is straightforward to evaluate successive states of the LFSR 1452 shown in FIG. 14. For example, the LFSR transitions from the state 00001 to the state 00010 since the one bit in the rightmost flop is clocked into the next to rightmost flop at the transition (all the other flops hold zeroes, as shown). Also, the LFSR transitions from the state 10000 to the state 00011 since the one bit in the leftmost flop is clocked into both the rightmost flop and also (via the XOR network, ⊕) into the next to rightmost flop at the transition. For large LFSRs, however, it may take an unacceptable amount of time to simulate the LFSR and generate all the LUTs' entries. In such a case, the fast LFSR simulation discussed below can be used instead. The LUTs can be further used during performance of the method to find some values, for example, the location rᵢ discussed in item 2 of the next paragraph below, required to compute the distance between the current LFSR state and the initial state.
3. For each mᵢ, find the corresponding integer vᵢ such that

$$\frac{m}{{m}_{i}} {v}_{i} ≡ 1 mod {m}_{i} .$$

For the case m=21, m₁=3, m₂=7, it can be checked that v₁=1 and v₂=5. Numbers vᵢ are also required for the LFSR distance computation as it will be shown in the next paragraph.

In one embodiment, each time DELTA is invoked, the following method acts are performed for a given content y of the LFSR corresponding to a given fault:
1. For each coefficient mᵢ, raise y treated as a polynomial to the power of m/mᵢ and divide the result by the LFSR characteristic polynomial p(x) to obtain the remainder y^{m/mi} mod p(x). Suppose the LFSR is in state 01010 (y=x³+x) and p(x)=x⁵+x+1. The corresponding remainders are then as follows:

y^{m/m}^{₁} modp(x)=(x³+x)^{21/3}mod x⁵+x+1=x⁴+x²+x=(10110)

y^{m/m}^{₂} modp(x)=(x³+x)^{21/7}mod x⁵+x+1=x⁴+x²+x=(10100)
2. For each remainder obtained in step 1, find its corresponding location rᵢ in the LUT—see FIG. 15. In this example, the first remainder, 10110, is g₁² in the LUT for m₁. The second remainder, 10100, is g₂⁴ in the LUT for m₂. Thus, r₁=2 and r₂=4, as shown in FIG. 15, which illustrates a searching of lookup tables in the discrete logarithm approach.
3. Determine the sum

$${\sum }_{i = 1}^{k} {r}_{i} \cdot \frac{m}{{m}_{i}} {v}_{i} mod m$$

to obtain the distance L between the current state of the LFSR and the initial state 0 . . . 001:

$$L = ( {r}_{1} \frac{m}{{m}_{1}} {v}_{1} + {r}_{2} \frac{m}{{m}_{2}} {v}_{2} ) mod m = ( 2 \cdot 7 \cdot 1 + 4 \cdot 3 \cdot 5 ) mod 21 = 11$$

Indeed, it can be checked that 01010 (that is, g11 in the LFSR listing 1453 of states (see FIG. 14)) is obtained from the initial LFSR 1452 state after 11 LFSR state transitions.

Applying DELTA to the failing words counter described above is straightforward. Similarly, if one wants to apply the method to the signature register also introduced above in the same section, DELTA is desirably invoked twice for each signature. This process is illustrated by the following two examples:

### EXAMPLE 1

Assume a single faulty cell cₓ produces the signature S(cₓ) 1654 in FIG. 16. FIG. 16 shows a signature register trajectory in a multiple input ring generator. In various embodiments, the reference distance L_{ref} 1655 between the initial state (0 . . . 0001) and the state corresponding to the faulty rightmost cell c₀ in the last row (R-1) is determined from its signature S(c₀) 1656. This state can be obtained as a result of a single injection to the empty MIRG at input b₁ (see FIG. 13). Next, the distance Lₓ 1657 between the initial state (0 . . . 0001) and the actual state of the MIRG is determined. The location of the faulty cell cₓ is x=Lₓ−L_{ref.} 1658.

### EXAMPLE 2

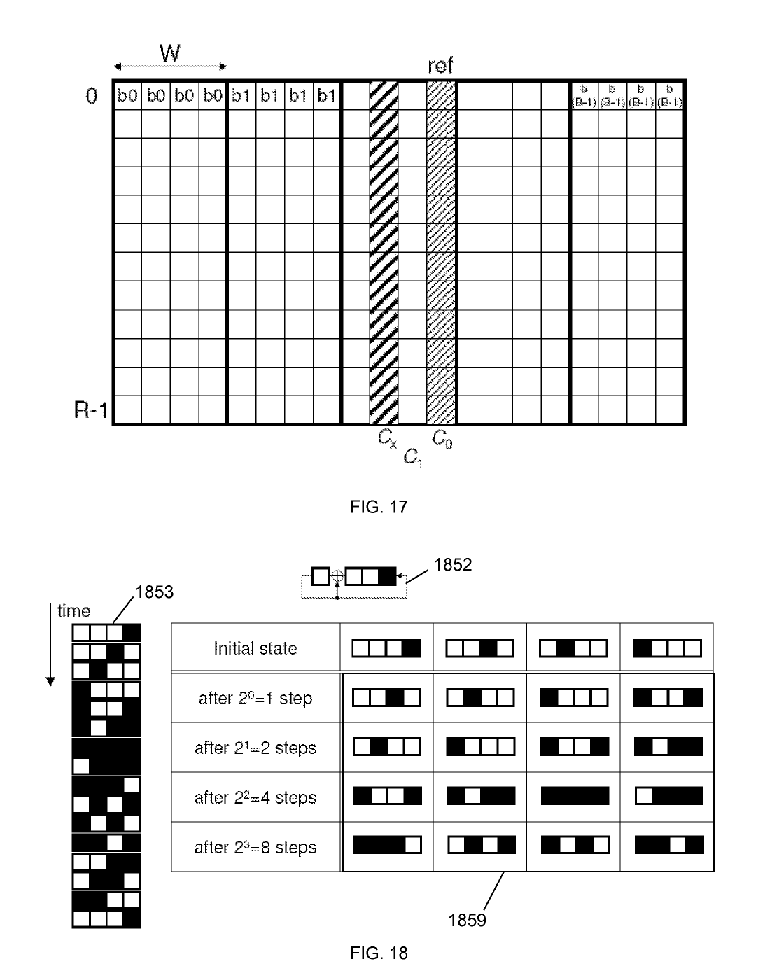

Consider a single column failure producing signature S(Cₓ). FIG. 17 illustrates a single column failure Cₓ and the reference column C. Here, the rightmost column C₀ of a given vertical segment of the memory array assumes the role of a reference. Since the MIRG is a linear circuit, a signature representing the reference column S(C₀) can be obtained by adding modulo 2 signatures produced by the faulty cells belonging to this column or stored in a LUT. Next, as shown in Example 1 above, the values of L_{ref} and Lₓ can be determined, and subsequently the actual location of the failing column.

A second diagnosis method is referred to herein as a fast LFSR simulation. In this technique, the state, after a given number of clock cycles, of an LFSR that has been has been initialized with an arbitrary combination of 0s and 1s can be determined in a time-efficient manner. Additional detail concerning this technique is provided in J. Rajski, J. Tyszer, “Primitive polynomials over GF(2) of degree up to 660 with uniformly distributed coefficients,” Journal of Electronic Testing: Theory and Application (JETTA), vol. 19, Kluwer Academic Publishers, 2003, pp. 645-657, hereby incorporated herein by reference in its entirety. As mentioned earlier, the fast LFSR simulation technique can be useful in obtaining states of the LFSR required by DELTA and other diagnostic techniques presented here.

Various embodiments of the techniques use an n×n LUT to store states of the n-bit LFSR after applying a certain number of clock cycles as shown in FIG. 18. FIG. 18 shows an example data structure for the fast LFSR simulation for the internal XOR LFSR implementing polynomial x⁴+x³+1. In FIG. 18, successive states of a 4-bit LFSR 1852 are shown 1853. In the 4×4 LUT 1859, only the first row of the table needs actual simulation to determine a content of the LFSR after applying a single clock cycle. Each column of the table corresponds to one of the initial states of the LFSR containing a single “one” in a designated position. Such states are referred to herein as singlet states. The next rows of the table are obtained exclusively by using the principle of superposition. FIG. 18 shows the LFSR states after 1, 2, 4, and 8 steps. For instance, the value in the second row and the last column is a sum of the first and the last column entries from the first row, as the preceding (above) signature consists of two ones corresponding to the first and the last column, respectively.

Using a table as shown in FIG. 18, one can easily determine the LFSR state after an arbitrarily chosen number x of cycles in no more than n steps. Each step can include up to n LUT inquiries; the computational complexity of this process is therefore O(n²). First, x is expressed as the sum of powers of 2. For each such component, the current content of the LFSR is broken down into single ones. Next, due to the principle of superposition, for each single one, the LFSR states from the LUT after a given number clock cycles are retrieved and bitwise XOR-ed giving the final state of the LFSR. The following example illustrates this technique.

### EXAMPLE

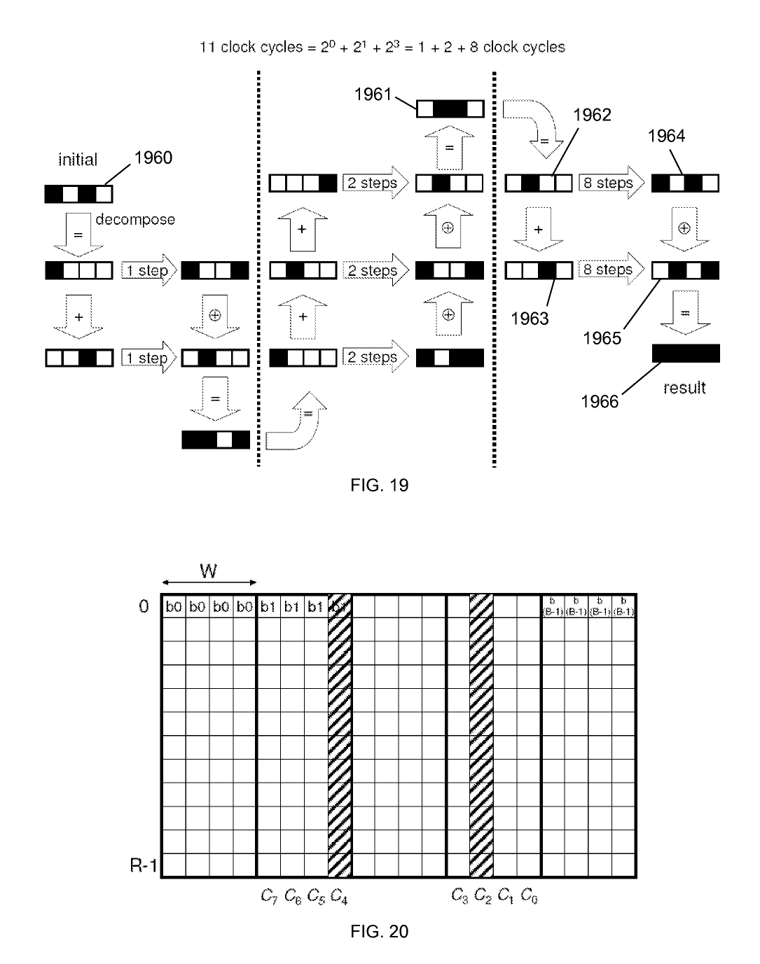

Let an internal XOR LFSR implement the primitive polynomial x⁴+x³+1 and be initialized to 1010, as shown 1960 in FIG. 19, which shows an example of a fast LFSR simulation. Suppose that the state the LFSR reaches after x=11 clock cycles is sought. Since 11=2⁰+1¹+2³, the technique can be performed in three steps as illustrated in FIG. 19. In the third step, for instance, the LFSR state 0110, shown at 1961, is broken down into two components: 0100 and 0010, shown in FIGS. 19 at 1962 and 1963, respectively. The table of FIG. 18 gives combinations 1010 and 0101 as the LFSR states reachable after 8 cycles and corresponding to the above combinations, and shown at 1964 and 1965 respectively. The sum of these two states yields the desired state of the LFSR, i.e., 1111, as shown 1966. The presented fast LFSR simulation technique is generally applicable to any type of linear finite state machines, including ring generators.

The discrete logarithm approach described above is capable of diagnosing failures where storing or generation of reference signatures is feasible. In certain cases, however, it might be impractical to produce all reference signatures. For instance, if two columns constitute a failure (FIG. 20), then the set of reference signatures would comprise 2·W items, and hence CPU time needed to perform diagnosis would be unacceptable.

In order to cope with more complicated failures, sets of linear equations can be employed. Consider, for example, a signature produced by a single row failure. Since a MIRG is a linear circuit, the corresponding signature can be easily obtained by adding bitwise failing signatures associated with individual memory cells of this particular row of. Moreover, multiple column/row failing signatures can be computed by adding modulo 2 signatures corresponding to single column/row failures. Hence, it may be possible to find defective rows or columns by solving a set of linear equations over GF(2). In these equations, Boolean-valued variables represent either columns or rows, and every equation corresponds to a single signature bit. They can be simplified by using, for instance, Gauss-Jordan elimination. Since the amount of failing columns/rows is known (via the FWC value, for example), solutions of anticipated multiplicity can be sought. If such a solution is not found, Gaussian elimination can be repeated for different sequences of pivot variables. Experiments indicate that in virtually 100% of cases, the first solution of the expected multiplicity is correct provided the size of the MIRG is large enough to ensure sufficient diagnostic resolution.

### EXAMPLE

Consider again a failure that involves two columns located in two vertical segments as shown in FIG. 20. From Table 2 (see failing pattern class No. 8), it can be observed that the failing column indicator indicates vertical segments of the memory array having failing columns. Therefore, variables corresponding only to the columns of the two segments are incorporated into the equations. The signatures of successive columns belonging to one vertical segment can be obtained from the signature stored in the look-up table and corresponding to the rightmost failing column in the segment by a simple one-step MIRG simulation per one column.

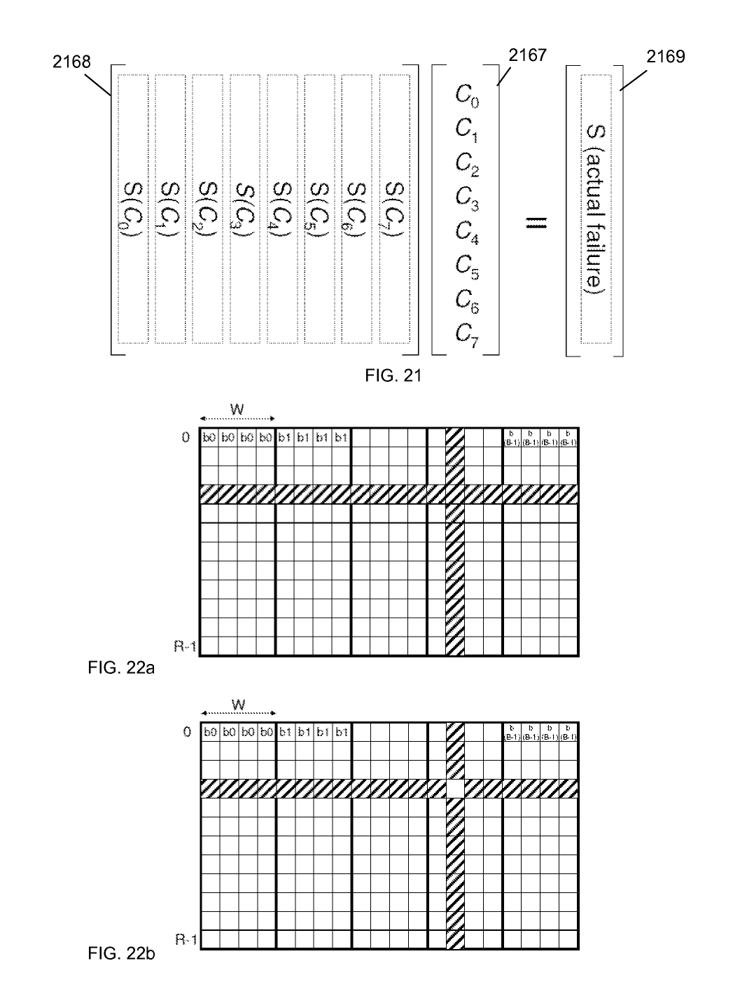

FIG. 21 gives, in the form of a matrix equation, the set of linear equations corresponding to the failure of FIG. 20, where C₀, C₁, . . . , C₇ of FIG. 20 are the Boolean variables assigned to respective columns in the memory array. These eight variables are arranged as a column vector 2167 in FIG. 21. S(Cᵢ) is a signature of the column associated with Cᵢ, corresponding to a failure in that column; that is, each S(Cᵢ) is a B-bit signature. The set of eight B-bit signatures is arranged, as shown in FIG. 21, as a B×8 matrix 2168. S(actual failure) is the actual failing signature observed, and is depicted as a B-bit column vector 2169. Using the information provided by FCI and FWC (=2R), solutions to the matrix equation of FIG. 21 where one variable from {C₀, . . . , C₃}, and one variable from {C₄, . . . , C₇} are set to 1 are sought. To increase the chance of finding the actual solution, one may repeat the Gaussian elimination process for different orders of pivots.

Finally, in certain cases, neither the DELTA nor linear equations methods can be employed due to the following phenomenon. Let a failure be composed of a single failing column and a single failing row. All failing cells are shown in FIG. 22a. Because the linear equations method employs the principle of superposition, its application would result in putting together signatures for a single row and a single column. However, the modulo 2 sum of these two signatures would actually produce another signature corresponding to a failure shown in FIG. 22b. As can be seen, there is a noticeable difference between these two figures. In the approach using the principle of superposition, the contribution of an “intersection” cell is canceled because it is added twice, modulo 2, whereas the actual test examines this cell only once. Because of this discrepancy, the solution cannot typically be found, and the use of another diagnostic technique is desirable. The following paragraphs describe an example of one such diagnostic technique.

In cases where failing rows and columns intersect, a signature simulation can be performed. Using one approach, “soft copies” of the signature register—that is, copies created in the memory of the diagnostic tool 2800 (see FIG. 28)—store partial signatures of the failing rows, columns, and “intersection” cells. Such soft copies may be referred to herein as soft signature registers. The partial signatures are subsequently XOR-ed for each mutual configuration, and their sum is compared against the actual failing signature. This is illustrated by the following example.

### EXAMPLE

Consider again a single column and a single row failure of FIG. 22a. The signature of the actual fault can be obtained by adding modulo 2 three signatures:

S(actual_failure)=S(row_{—}x)+S(column_{—}y)+S(cell_(x,y)) (1)

The reference signatures corresponding to the failing row, column and cell are stored in the LUT. Three soft signature registers Sᵣ, S_{c}, and Sᵢ can be used to represent signatures associated with a row, a column and an intersection cell, respectively.

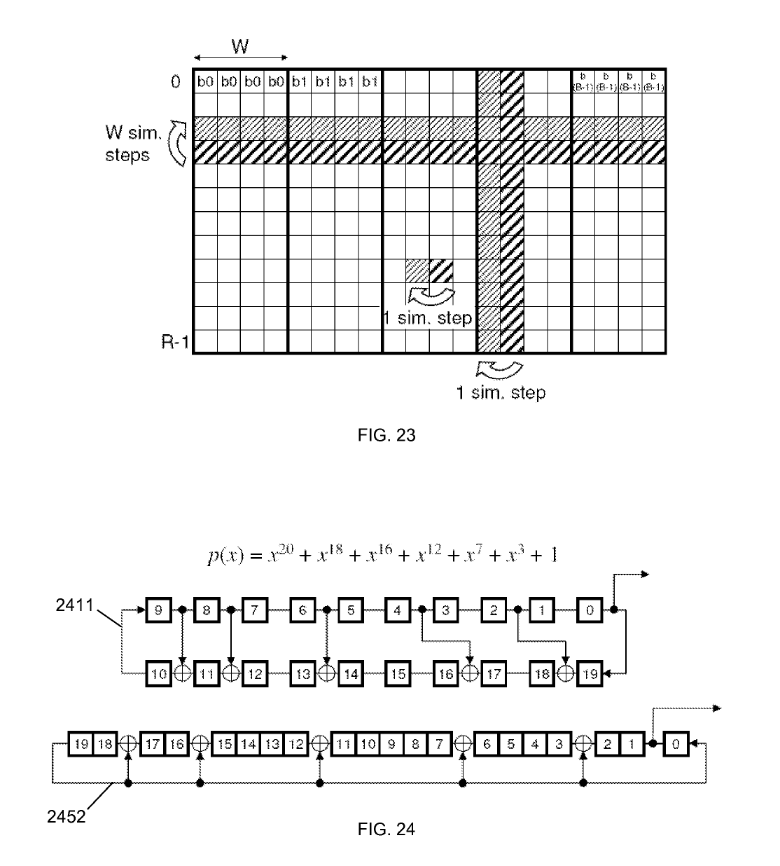

According to various embodiments, the process of signature simulation can include the following:
1. Retrieve row, column and cell signatures stored in the LUTs, and assign them to Sᵣ, S_{c}, and Sᵢ, respectively.
2. If the equation (1) is satisfied, then the solution is found; otherwise:
3. Advance S_{c} and Sᵢ by 1 step (see FIG. 23, which shows a MIRG simulation used to obtain signatures for failures in neighboring cells).
4. If the number of the simulation steps for Sᵢ has reached the value of W, advance Sᵣ by W steps (obtaining the signature for the next failing row), reassign the column signature from the LUT and go back to step 2.

For the failure shown in FIG. 22a, the simulation performs up to W·R comparisons and approximately 3 (W·R) simulation steps of a ring generator (RG) in the worst case.

### Mapping a Ring Generator Into a Galois LFSR Trajectory

As noted above, some embodiments of the disclosed technology use ring generators to implement counters and signature registers. However, the DELTA method presented above typically uses an LFSR capable of dividing polynomials. Furthermore, the only device with such ability is a Galois (internal XOR) LFSR. In order to use ring generators instead of Galois LFSRs, the ring generator trajectory can be mapped into a trajectory of the internal XOR LFSR. This can be done provided that a ring generator preserving the transition function of a respective LFSR is used. See, e.g., J.-F. Li, C.-W. Wu, “Memory fault diagnosis by syndrome compression,” Proc. DATE, 2001, pp. 97-101. Thus, both the LFSR and the ring generator can produce the same maximum length sequence or m-sequence. An example of such equivalent devices is shown in FIG. 24. In FIG. 24, the LFSR 2452 and the ring generator 2411 are equivalent in that they generate the same m-sequence, and both have the characteristic polynomial p(x)=x²⁰+x¹⁸+x¹⁶+x¹²+x⁷+x³+1.

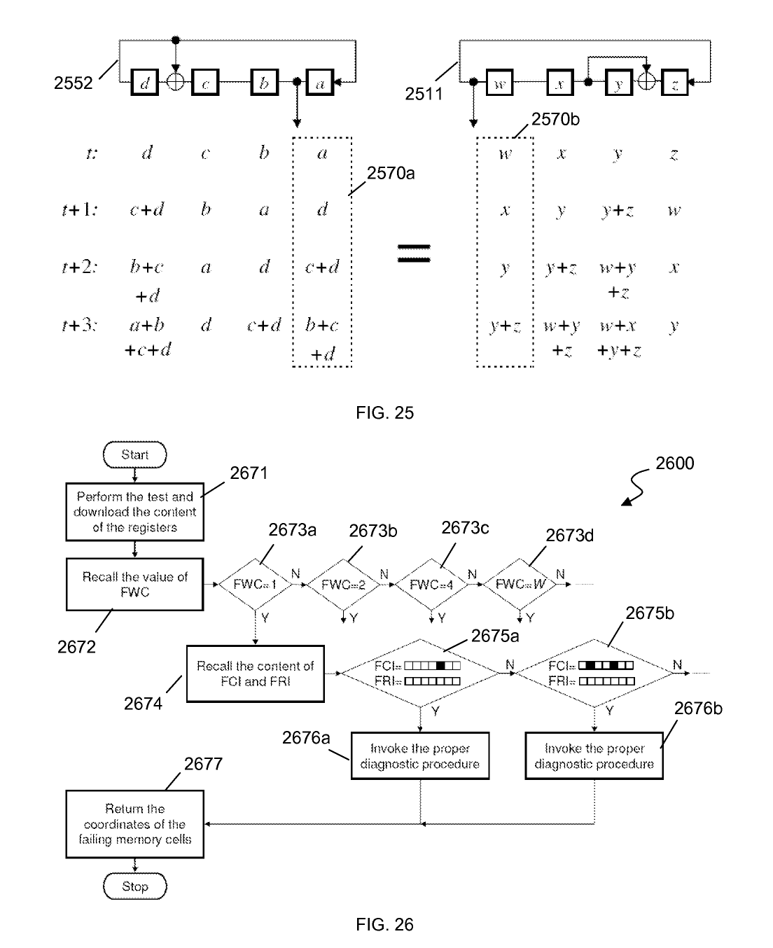

FIG. 25 shows how a mapping may be obtained between states of an LFSR and states of an equivalent ring generator. In order to find a state mapping function, and in one embodiment of the disclosed technology, one determines and equates at least M consecutive values occurring on the corresponding ring generator (RG) 2511 and LFSR 2552 outputs, where M is ring generator size in bits. A symbolic simulation is performed of both devices for M clock cycles and the output values of the LFSR 2552 and RG 2511 are matched as presented in FIG. 25 for the characteristic polynomial p(x)=x⁴+x³+1. The output values to be matched appear in the frames 2570a and 2570b. A set of linear equations is created in variables corresponding to the values of respective LFSR/RG flip-flops in M successive clock cycles:

$$a = w \\ d = x \\ d + c = y \\ d + c + b = y + z \qquad ( 2 )$$

By using symbolic Gaussian elimination, the above equations can be simplified as follows:

$$a = w \\ d = x \\ c = x + y \\ b = z \qquad ( 3 )$$

### EXAMPLE

Assume that the ring generator has reached state wxyz=1110. Equations (3) yield the corresponding state of the Galois LFSR which is, in this particular case, equal to abcd=1001. This conclusion can be confirmed in a different way by performing an exhaustive simulation of the LFSR 2552 and RG 2511, as presented in Table 3. As can be seen, the RG state wxyz=1110 corresponds to the LFSR state abcd=1001 and vice versa.

TABLE 3
LFSR and RG simulation

| | LFSR state, abcd | RG state, wxyz |
|---|---|---|
| 1. | 0001 | 1000 |
| 2. | 0010 | 0001 |
| 3. | 0100 | 0010 |
| 4. | 1000 | 0110 |
| 5. | 1001 | 1110 |
| 6. | 1011 | 1111 |
| 7. | 1111 | 1101 |
| 8. | 0111 | 1011 |
| 9. | 1110 | 0101 |
| 10. | 0101 | 1010 |
| 11. | 1010 | 0111 |
| 12. | 1101 | 1100 |
| 13. | 0011 | 1001 |
| 14. | 0110 | 0011 |
| 15. | 1100 | 0100 |
| | 0001 | 1000 |

### Look-Up Table of Failing Patterns

The grouping into classes shown in Table 2 can be used to set up a look up table for failing patterns where the lookup table uses FWC, FCI, and FRI values to determine the failing patterns that may correspond to these location information values. Thus, in order to accelerate diagnostic procedures for the most prevalent failing patterns, signatures of certain representative faults can be stored in an LUT. Once determined, they can be subsequently employed as a reference. Examples of pre-computed signatures that can be deployed in embodiments of the disclosed MBIST diagnostic schemes are summarized in Table 4.

TABLE 4.
Failing pattern look up table

| Pattern | | | LUT |
|---|---|---|---|
| no. | Pattern class | Corresponding failing pattern | size |
| 1 | One cell | 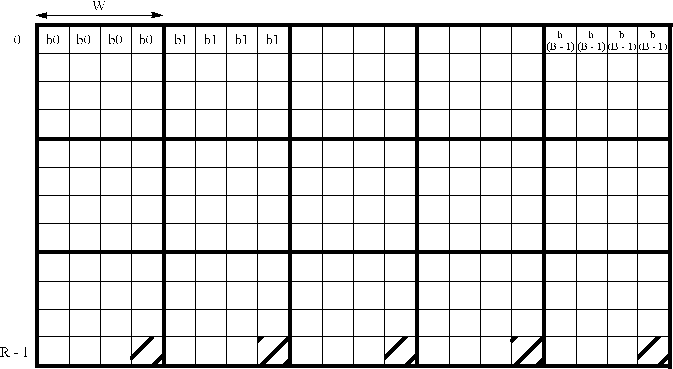 | B |
| 2 | Two neighbors (horizontally) | 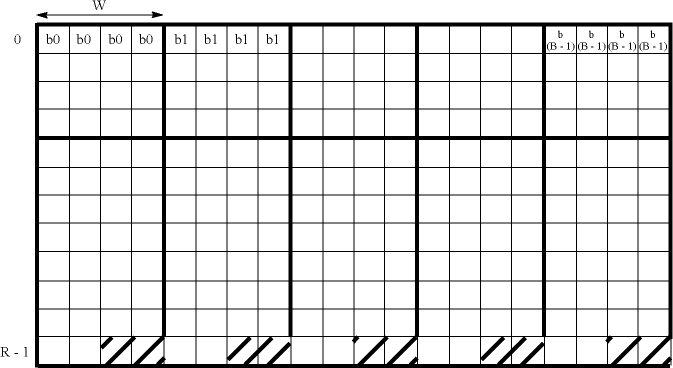 | B |
| 3 | Two neighbors (horizontally) in two neighboring segments | 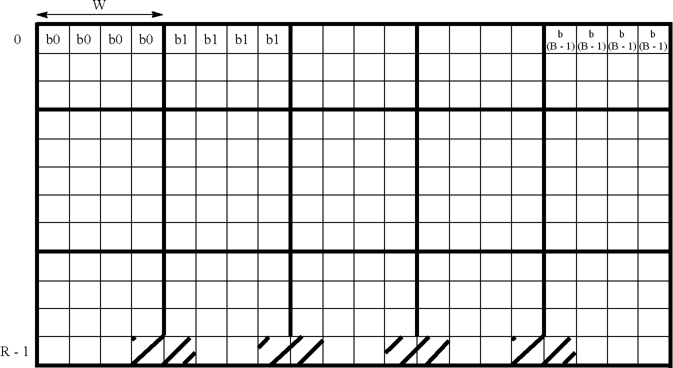 | B − 1 |
| 4 | Two neighbors (vertically) | 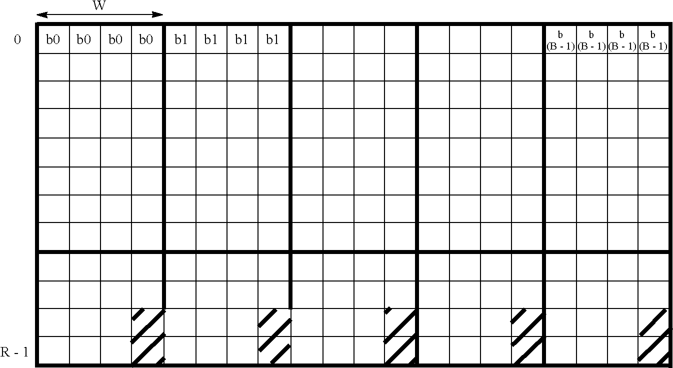 | B |
| 5 | Two of rising diagonal | 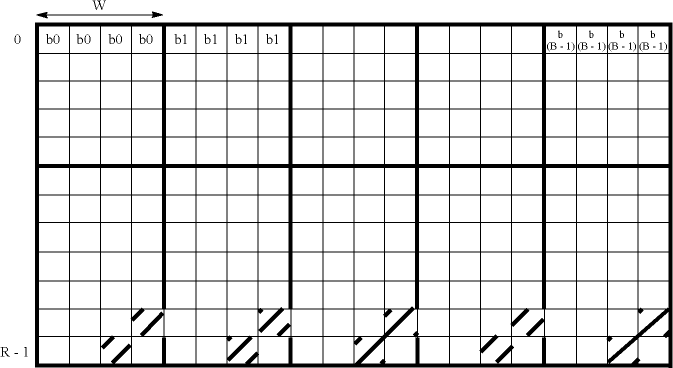 | B |
| 6 | Two of rising diagonal in two neighboring segments | 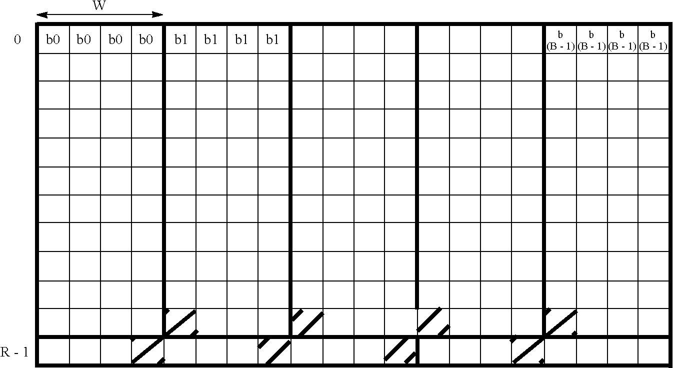 | B − 1 |
| 7 | Two of falling diagonal | 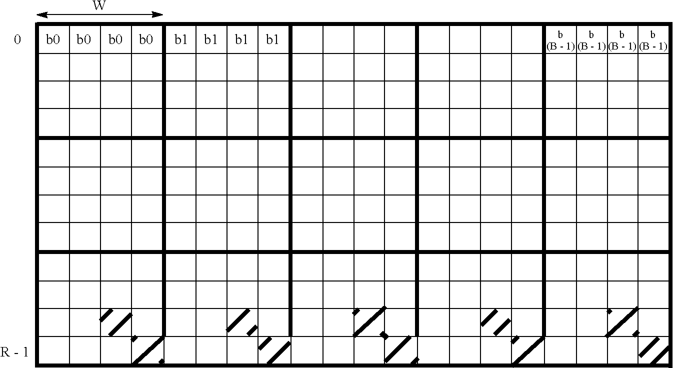 | B |
| 8 | Two of falling diagonal in two neighboring segments | 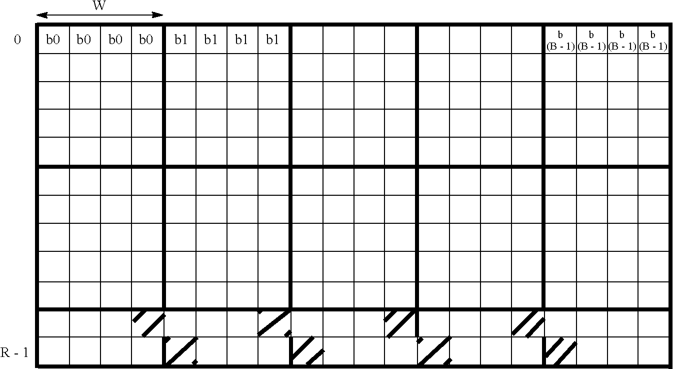 | B − 1 |
| 9 | 2x2 | 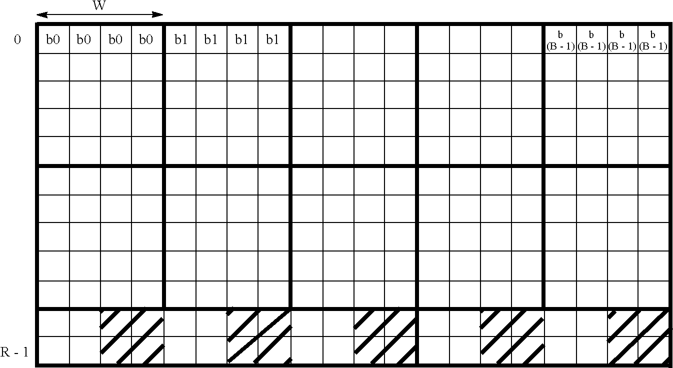 | B |
| 10 | 2x2 in two neighboring segments | 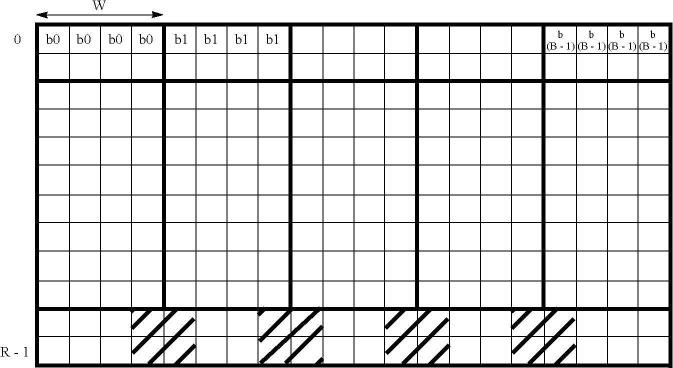 | B − 1 |
| 11 | One column | 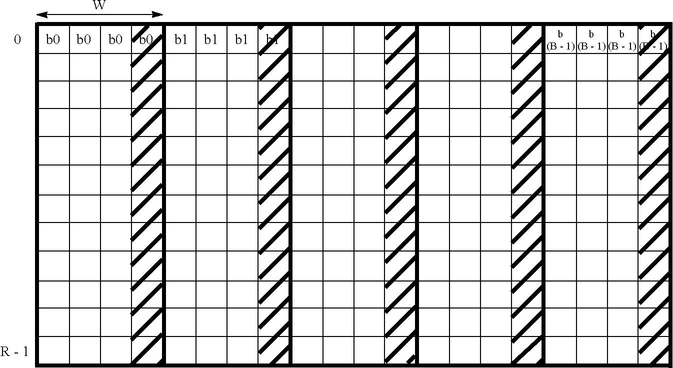 | B |
| 12 | One row | 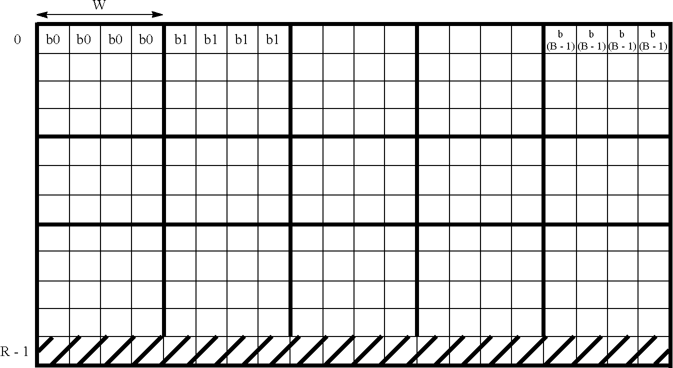 | 1 |
| 13 | One row 010101 | 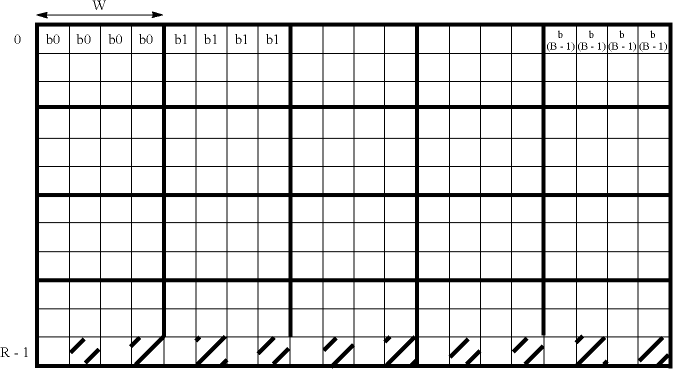 | 1 |

### Failing Patterns and the Corresponding Diagnostic Techniques

As discussed above, a variety of diagnosis schemes can be employed to process the location information and compacted signature data resulting from memory test failures. This section, and its subsections, provide examples of failing patterns along with techniques for handling them based on the contents of the FWC, FCI and FRI registers. Although the examples provided below include numerical references indicating one possible flow, the described method acts may in some cases be performed in a different order or simultaneously. FIG. 26 is a flowchart illustrating an embodiment of an overall memory diagnostic flow used in these examples. FIG. 26 will be discussed further following discussion of the subsections A to R referenced in Table 5. The actions which are invoked in each particular case are summarized in Table 5. Note that variable P is used in this section to denote a period of an M-bit MIRG. Typically, P is equal to 2M−1.

TABLE 5
Failing patterns

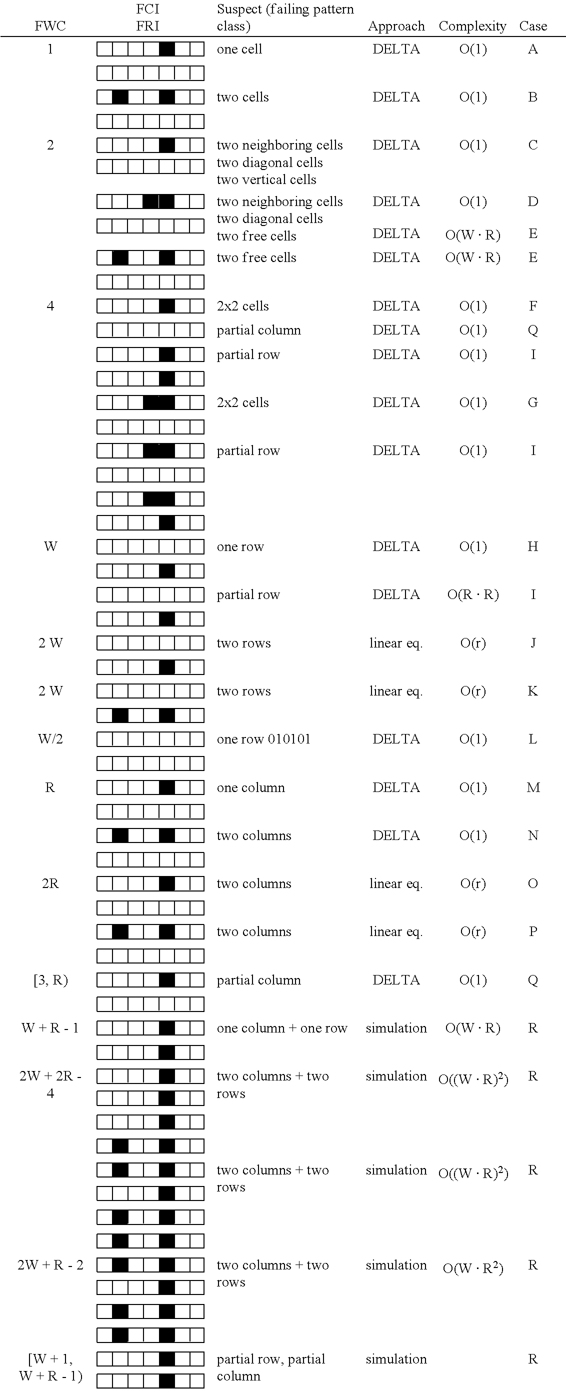

Diagnosis strategies for the failing patterns in Table 5 are now described in the following cases.

### Case A. One Cell

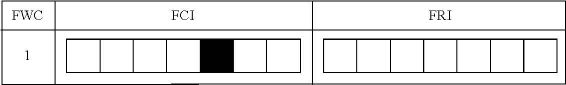

1. Determine the distance Lₓ between state 0 . . . 01 of the MIRG and its current state.
2. Get the reference signature of a single cell failure from the LUT.
3. Determine the reference distance L_{ref}.
4. L←Lₓ−L_{ref}; if L<0, then L←L+P.
5. Assert that L<W·R.
6. Return coordinates (x, y) of a failing cell as follows: x=W−1−(L mod W), y=R−1−L/W, (x is the column number within a failing sector).

### Case B. Two Cells

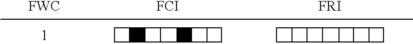

1. Determine the distance Lₓ between state 0 . . . 01 of the MIRG and its current state.
2. Get the reference signatures of single cell failures of the corresponding memory sectors from the LUT and XOR them to obtain the actual reference signature.
3. Determine the reference distance L_{ref}.
4. L←Lₓ−L_{ref}; if L<0, then L←L+P.
5. Assert that L<W·R.
6. Return coordinates (x, y) of the failing cells as follows: x=W−1−(L mod W), y=R−1−L/W, (x is the column number within a failing sector).

### Case C. Two Neighboring/Diagonal/Vertical Cells

1. Determine the distance Lₓ between state 0 . . . 01 of the MIRG and the actual MIRG state.
2. Get the reference signatures of the double cell failures from the LUT:
   a) two neighboring cells (see Pattern 2 in Table 4),
   b) two vertical cells (see Pattern 4 in Table 4),
   c) two diagonal cells (see Pattern 5 in Table 4),
   d) two diagonal cells (see Pattern 7 in Table 4).
3. Determine the corresponding reference distances L_{ref}_{_{—}}ₐ, L_{ref}_{_{—}}_{b}, L_{ref}_{_{—}}_{c}, L_{ref}_{_{—}}_{d}.
4. Lₐ←Lₓ−L_{ref}_{_{—}}ₐ, L_{b}←Lₓ−L_{ref}_{_{—}}_{b}, L_{c}←Lₓ−L_{ref}_{_{—}}_{c}, L_{d}←Lₓ−L_{ref}_{_{—}}_{d}. If a particular L_{a/b/c/d}<0, then L_{a/b/c/d}←L_{a/b/c/d}+P.
5. L←min {Lₐ, L_{b}, L_{c}, L_{d}}.
6. Assert that L<W·R. If not, proceed as in Case E (two free cells in the same sector).
7. Retrieve corresponding failing cells' coordinates from the LUT, and return their values further decreased by the row/column offsets sᵣ=L/W and s_{c}=(L mod W).

### Case D. Two Neighboring/Diagonal Cells (In Two Neighboring Sectors)

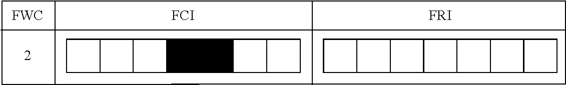

1. Determine the distance Lₓ between state 0 . . . 01 of the MIRG and the actual MIRG state.
2. Get the reference signatures of the double cell failures from the LUT:
   a) two neighboring cells (see Pattern 3 in Table 4),
   b) two diagonal cells (see Pattern 6 in Table 4),
   c) two diagonal cells (see Pattern 8 in Table 4).
3. Determine the corresponding reference distances L_{ref}_{_{—}}ₐ, L_{ref}_{_{—}}_{b}, L_{ref}_{_{—}}_{c}.
4. Lₐ←Lₓ−L_{ref}_{_{—}}ₐ, L_{b}←Lₓ−L_{ref}_{_{—}}_{b}, L_{c}←Lₓ−L_{ref}_{_{—}}_{c}. If a particular L_{a/b/c}<0, then L_{a/b/c}←L_{a/b/c}+P.
5. L←min {Lₐ, L_{b}, L_{c}}.
6. Assert that (L mod W)=0 and L<(R−1)·W.
7. Retrieve corresponding failing cells' coordinates from the LUT and return their values further decreased by the row offset sᵣ=L/W.

### Case E. Any Two Cells

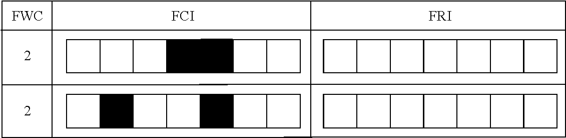

1. Get (from the LUT) the reference signature of a single cell of the first sector that captures a failure.
2. Determine the reference distance L_{ref} between state 0 . . . 01 of the MIRG and the reference signature of step 1.
3. Get (from the LUT) the reference signature of a single cell of the second failing sector.
4. Create a soft copy S of the actual signature register, that is, a copy of the signature register in the memory of the diagnostic tool, and initialize the copy S with the signature obtained in step 3.
5. Repeat W·R times:
   XOR the actual fault signature with the current content of S (to neutralize a contribution of the failing cell from the second sector into the actual signature).
   Determine the distance Lₓ between state 0 . . . 01 of the MIRG and the signature of the XOR step just performed.
   L←Lₓ−L_{ref}; if L<0, then L←L+P.
   If L<W·R, the two failing cells are found. L determines the location of the failing cell from the first sector similarly as in Case A; S stores the signature of the failing cell from the second sector. Stop the algorithm and return the results. Otherwise:
   Simulate S for one clock cycle and go to the XOR step (simulating the MIRG for one cycle results in determining the signature of the adjacent failing cell as indicated in FIG. 23).

### Case F. 2×2 Cells

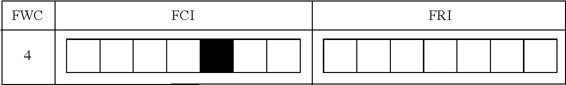

1. Determine the distance Lₓ between state 0 . . . 01 of the MIRG and the actual MIRG state.
2. Get the reference signature of 2×2 cells failure from the LUT.
3. Determine the reference distance L_{ref}.
4. L←Lₓ−L_{ref}; if L<0, then L←L+P.
5. Assert that L<W·(R−1)−1.
6. Retrieve the failing cells' coordinates from the LUT, and return their values further decreased by the row/column offsets sᵣ=L/W and s_{c}=(L mod W).

### Case G. 2×2 Cells in Two Neighboring Sectors

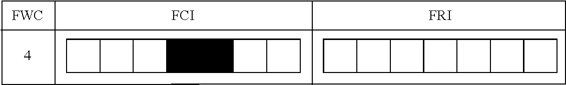

1. Determine the distance Lₓ between state 0 . . . 01 of the MIRG and the actual MIRG state.
2. Get the reference signature of 2×2 cells failure from the LUT (pattern 10 in Table 4).
3. Determine the reference distance L_{ref}.
4. L←Lₓ−L_{ref}; if L<0, then L←L+P.
5. Assert that L<W·(R−1) and (L mod W)=0.
6. Retrieve the failing cells' coordinates from the LUT, and return their values further decreased by the row offset sᵣ=L/W.

### Case H. One Row

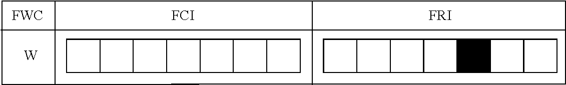

1. Determine the distance Lₓ between state 0 . . . 01 of the MIRG and the actual MIRG state.
2. Get the reference signature of a single row failure from the LUT (pattern 12 in Table 4).
3. Determine the reference distance L_{ref}.
4. L←Lₓ−L_{ref}; if L<0, then L←L+P.
5. Assert that L<W·R and (L mod W)=0.
6. Return the number of the failing row as R−1−L/W.

### Case I. Partial Row

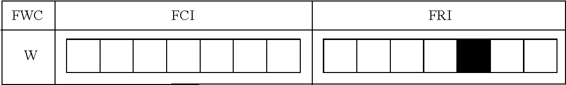

Since the exact number of failing cells in a row is unknown in this case, DELTA has to be used more than once (W² times in the worst case). Each time, a different combination of adjacent failing cells in boundary failing sectors is examined by the following routine:
1. Determine the distance Lₓ between state 0 . . . 01 of the MIRG and the actual MIRG state.
2. Build the reference signature of failing cells by using signatures of single failures from the LUT.
3. Determine the reference distance L_{ref}.
4. L←Lₓ−L_{ref}; if L<0, then L←L+P.
5. Assert that L<W·R and (L mod W)=0.
6. Return the number of the failing row as R−1−L/W. Numbers of actual failing cells are given by the signature created in step 2.

### Case J. Two Rows

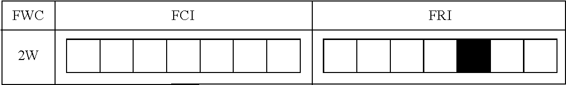

1. Create a copy S of the actual signature register.
2. Initialize S with the reference signature of a single row from the LUT (pattern 12 in Table 4).
3. Create a set of M+1 linear equations. Each equation describes values of a single flip-flop of the signature register (right-hand side). Each variable (left-hand side) corresponds to a single memory array row of the failing segment. The row signatures are generated by applying W clock cycles to S (see FIG. 23). An additional equation has exactly W ones on the left-hand side and zero on the right-hand side. Since the multiplicity of the solution is known a priori and is even, this equation is used to avoid solutions of odd multiplicity.
4. There are standard methodologies for implementing Gaussian elimination, in which typical values of parameters relating to numerical solution, for example, a maximum number of iterations to be performed, may be specified. In this disclosure, one such parameter is denoted maxSolverRuns. In this step, repeat up to maxSolverRuns times:
   (a) Make a copy of the set of linear equation and shuffle variables randomly.
   (b) Simplify the equations using Gauss-Jordan elimination.
   (c) If the multiplicity of the solution is 2, return the non-zero variables indicating the failing memory rows and stop the algorithm. Otherwise go back to step (a).

### Case K. Two Rows

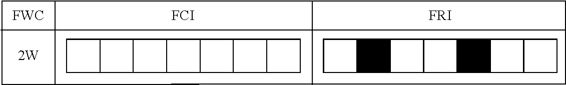

Searching for two failing rows in two memory segments proceeds in a way similar to that of Case J except the following:
1. The number of variables is 2W since rows from two segments constitute new equations.
2. There are two additional equations which help to find the actual solution. They ensure generation of solutions in which two rows belong always to two segments. These extra equations can be formed, for instance, as follows:

a+b+c+d=1

w+x+y+z=1
where a, b, c, and d are variables corresponding to rows of the first sector, while w, x, y, and z correspond to rows of the second sector.

### Case L. One Row 010101

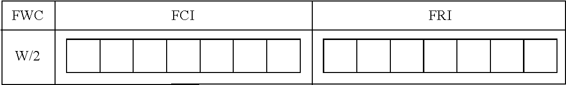

1. Determine the distance Lₓ between state 0 . . . 01 of the MIRG and the actual MIRG state.
2. Get the reference signature of a single failing row 010101 from the LUT (pattern 13 in Table 4).
3. Determine the reference distance L_{ref}.
4. L←Lₓ−L_{ref}; if L<0, then L←L+P.
5. Assert that L<W·R and (L mod W) ε {0,1}.
6. Return the number of the failing row as R−1−L/W. If (L mod W)=0, then the failing row starts with the correct cell (010101 . . . ), otherwise the first cell in the row is failing (101010 . . . ).

### Case M. One Column

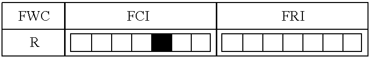

1. Determine the distance Lₓ between state 0 . . . 01 of the MIRG and its actual state.
2. Get the reference signature of a single failing column from the LUT (pattern 11 in Table 4).
3. Determine the reference distance L_{ref}.
4. L←Lₓ−L_{ref}; if L<0, then L←L+P.
5. Assert that L<W.
6. Return the number of the failing column as W−1−L.

### Case N. Two Columns

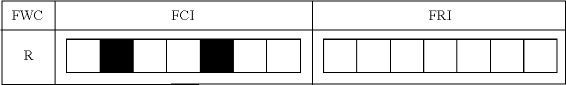

1. Determine the distance Lₓ between state 0 . . . 01 of the MIRG and its actual state.
2. Get signatures of single column failures from the LUT (pattern 11 in Table 4) corresponding to failing sectors and XOR them to obtain the reference signature.
3. Determine the reference distance L_{ref}.
4. L←Lₓ−L_{ref}; if L<0, then L←L+P.
5. Assert that L<W.
6. Return the numbers of the failing columns as W−1−L (columns' numbers are within failing sectors).

### Case O. Two Columns

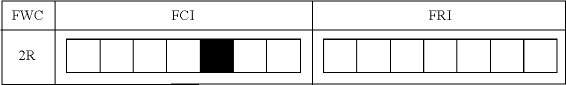

1. Create a soft copy S of the actual signature register.
2. Initialize S with the reference signature of a single column failure corresponding to the failing sector from the LUT (pattern 11 in Table 4).
3. Create a set of M+1 linear equations. Each equation describes values of a single flip-flop of the signature register (right-hand side). Each variable (left-hand side) corresponds to a single memory array column of the failing segment. The column signatures are generated by applying single clock cycles to S (see FIG. 23). Additional equation has exactly W ones on the left-hand side and zero on the right-hand side. Since the multiplicity of the solution is known a priori and is even, the additional equation is used to prevent generation of odd multiplicity solutions.
4. Repeat up to maxSolverRuns times:
   (a) Make a working copy of the set of linear equation and shuffle variables randomly.
   (b) Simplify the equations using Gauss-Jordan elimination.
   (c) If the multiplicity of the solution is 2, return the non-zero variables indicating the failing memory columns and stop the algorithm. Otherwise go to step (a).

### Case P. Two Columns

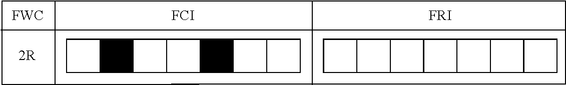

Searching for the two failing columns in two memory segments proceeds in a way similar to that presented in Case N above except for the following:
3. The number of variables is 2W since the columns from two segments constitute the equations.
4. There are two additional equations which help to find the actual solution. They ensure generation of solutions in which two columns belong always to two segments. These extra equations can be formed, for instance, as follows:

a+b+c+d=1

w+x+y+z=1
where a, b, c, and d are variables corresponding to columns of the first sector, while w, x, y, and z correspond to columns of the second sector.

### Case Q. Partial Column

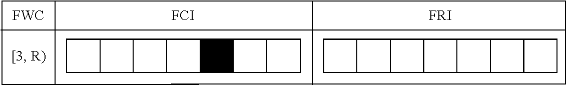

1. Determine the distance Lₓ between state 0 . . . 01 of the MIRG and the actual MIRG state.
2. Generate the reference signature by XORing the signature of a single cell failure from the LUT with its regular offset every W cycles (see FIG. 23). This operation is to be repeated as many times as indicated by the content of FWC.
3. Determine the reference distance L_{ref}.
4. L←Lₓ−L_{ref}; if L<0, then L←L+P.
5. Assert that L<=W·(R−FWC).
6. Return the failing cells' coordinates as the reference cells' coordinates further decreased by the row/column offsets sᵣ=L/W and s_{c}=(L mod W).

### Case R. One (Partial)/Two Column(s)+One (Partial)/Two Row(s)

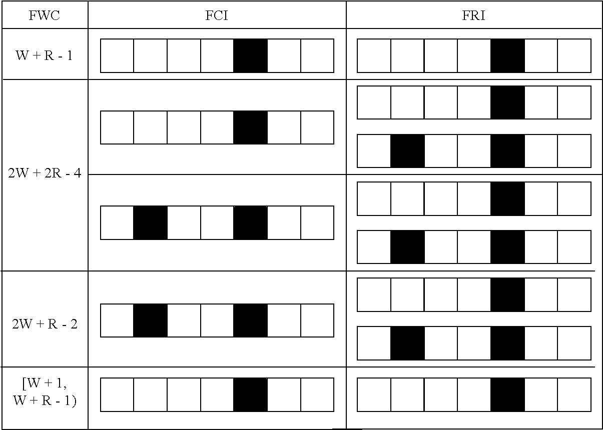

In cases where failing cells belonging to rows or columns are assumed to intersect, the simulation method can be used as discussed above in connection with FIG. 22a and FIG. 22b. Each time such a failing pattern is examined, all possible configurations of rows and columns are desirably checked by XORing them together with the signature of the intersection cell(s) and then the resultant sum is compared against the actual failing signature.

### Embedded Memory Diagnosis Method and Diagnostic Tool

Turning now to a discussion of the practice of failure diagnosis, FIG. 26 shows an embodiment 2600 of an overall memory diagnostic flow used in reference to the examples cited in Table 5. As discussed above, in a step 2671 the ATE directs the MBIST controller to perform the test and then signals the IC device to download the content of the signature register 210 and location information registers 211, 213, and 214. The ATE provides the content of the signature register 210 and location information registers 211, 213, and 214 to a diagnostic tool. The diagnostic tool retrieves the value of the FWC 2672. As noted in Tables 3 and 6, the FWC can have particular values, each of those values corresponding to particular classes of failing patterns. In a series of steps 2673a, 2673b, 2673c, and 2673d, as well as other steps not shown in FIG. 26, the value of FWC may be compared with each of the possible values, until a match is found. FIG. 26 illustrates the example case where a match is found 2673a for FWC=1. The diagnostic tool retrieves the values of FCI and FRI 2674, and compares 2675a, 2675b against lookup table values (see Table 5) until a match is found. Depending on the results of the comparison with the lookup table, a diagnostic procedure is invoked 2676a, 2676b, and so on. After the diagnostic procedure is performed, the coordinates of the failing memory cells are returned 2677.

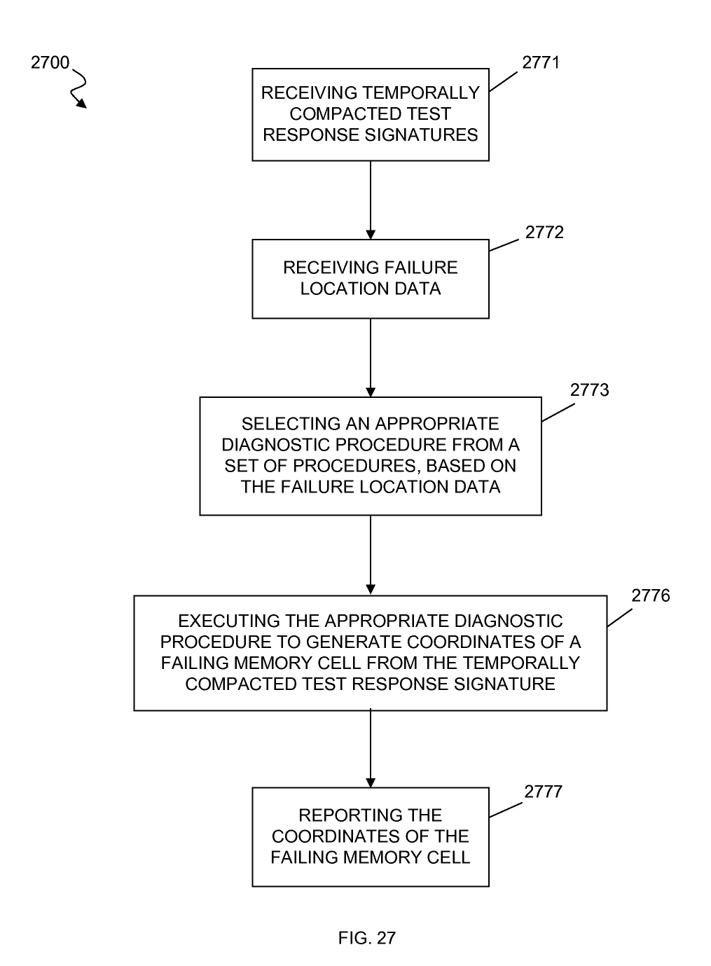

FIG. 27 is a flowchart according to an embodiment of a method 2700 for diagnosing memory test failures. The steps of the method 2700 may be performed for example in a diagnostic tool (see FIG. 28). After the ATE receives temporally compacted test response signatures and failure location information from the integrated circuit device under test, the diagnostic tool receives 2771 temporally compacted test response signatures from the ATE. As discussed above, in various embodiments the ATE receives the compacted signatures from a signature register of the integrated circuit device. In various other embodiments, as previously discussed, the ATE receives the compacted signatures from a shadow register in the integrated circuit device.

The diagnostic tool in addition receives 2772 failure location information of the integrated circuit device from the ATE. It will be appreciated that in various embodiments the steps 2771 and 2772 may take place concurrently; in various other embodiments one step may follow the other in a particular order. Also, as discussed above, in various embodiments the ATE receives the failure location information from a failing words counter, failing column indicator, and failing row indicator of the integrated circuit device. In various other embodiments, as previously discussed, the ATE receives the failure location information from shadow registers in the integrated circuit device. Moreover, typically the compacted signatures and the failure location data are transferred from the shadow registers to the ATE in response to a signal from the ATE.

As discussed above in connection with Table 5, analysis of filing patterns allows for creation of a lookup table for use in determining a diagnostic procedure to apply, according to the values stored in the filing words counter (FWC), the failing column indicator (FCI), and the filing row indicator (FRI). For example, the FWC, FCI, and FRI values can be used to generate an index into the lookup table. Whether by using the index, or by another method, the diagnostic tool selects 2773 a diagnostic procedure from the set of diagnostic procedures discussed above, based on the failure location data.

Next, the selected diagnostic procedure is executed 2776 in the diagnostic tool to generate coordinates of a failing memory cell from the temporally compacted test response signature. Some test response signatures may indicate more than one failing memory cell. In those cases, the diagnostic procedure executed 2776 in the diagnostic tool generates coordinates for more than one failing memory cell.

After coordinates of the failing memory cell(s) have been determined, the diagnostic tool reports 2777 the coordinates. As discussed in connection with the example fault dictionary in Table 1, the coordinates of the failing memory cells may be used to construct monochrome or color bitmaps for display of memory failure information. It is understood that the reporting of the coordinates of the failing memory cells can include display or printout of such bitmaps.

FIG. 28 shows a diagnostic tool 2800 according to an embodiment. The diagnostic tool 2800 may implement, for example, the method of FIG. 27. As shown, the diagnostic tool 2800 includes a controller 2878 that can execute instructions. The instructions may be stored, for example, in a memory 2879. The memory 2879 may also be configured to store data, for example data downloaded from an ATE device that includes diagnostic data of an integrated circuit device under test.

In various embodiments a user interface 2880 provides for display of data or results, for example on a display device 2881, or may output results and data by for example a printer or plotter (not shown). The user interface 2880 also provides for receipt of user input via, for example, one or more input devices 2882 such as, for example, a keyboard, touch screen, mouse, or other pointing device. It is understood that any suitable device for display of results or data, and any suitable device for receipt of user input, is within the scope of this disclosure.

The diagnostic tool device 2800 in addition includes a set of modules 2883, that may be implemented for example, as instructions in software, or may be hardware implementations. It should be appreciated that some modules may be implemented in software and other modules may be implemented as hardware.

The modules 2883 include a signature receipt module 2871, configured to receive temporally compacted test response signatures, for example, from a signature register of the integrated circuit device, or from a corresponding shadow register for the signature register, as described above, and according to the step 2771 of the method 2700 (see FIG. 27). The modules 2883 also include a location receipt module 2872, configured to receive failure location information, for example, from the FWC, FCI, and FRI components of the integrated circuit device, or from corresponding shadow registers for those components, as described above, and in accordance with the step 2772 of the method 2700 (see FIG. 27).

In addition, the diagnostic tool includes a diagnostic selection module 2873 that is configured to select a diagnostic procedure from a set of diagnostic procedures as discussed above, based on the failure location data. The selection of a diagnostic procedure may be performed by the diagnostic selection module 2873, for example, in accordance with the step 2773 described above. The modules 2883 further include a diagnosis module 2876 configured to execute the selected diagnostic procedure to generate coordinates of a failing memory cell from the temporally compacted test response signature, in accordance with the step 2776 of the method 2700 described above. A reporting module 2877 included with the modules 2883 is configured to report the coordinates of the failing memory cells that have been determined, according to, for example, the step 2777 discussed above.

### CONCLUSION

Having illustrated and described the principles of the disclosed technology, it will be apparent to those skilled in the art that the disclosed embodiments can be modified in arrangement and detail without departing from such principles. In view of the many possible embodiments, it will be recognized that the illustrated embodiments include only examples and should not be taken as a limitation on the scope of the disclosed technology. Rather, the disclosed technology includes all novel and nonobvious features and aspects of the various disclosed apparatus, methods, systems, and equivalents thereof, alone and in various combinations and subcombinations with one another. While the invention has been described with respect to specific examples including presently preferred modes of carrying out the invention, those skilled in the art will appreciate that there are numerous variations and permutations of the above described systems and techniques that fall within the spirit and scope of the invention as set forth in the appended claims.

1. A method of testing embedded memory, comprising:
operating a memory built-in self-test controller of an integrated circuit device to apply a test step to test embedded memory of the integrated circuit device;
generating a plurality of test response signatures for failed memory tests;
temporally compacting the test response signatures using a linear feedback structure;
collecting memory location information associated with a failed memory test; and
providing the temporally compacted test response signatures and the collected memory location information to a diagnostic tool for use in a memory fault diagnosis process

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. A circuit for testing memory arrays, comprising:
a comparator generating test response signatures by comparing test response data from a memory array with expected test response data;
a signature register collecting the test response signatures and generating compacted test response signatures; and
one or more location data collectors collecting the test response signatures to generate error location information.

54. The circuit recited in claim 53, wherein the comparator is an XOR network.

55. The circuit recited in claim 53, wherein the signature register is a linear finite state machine.

56. The circuit recited in claim 55, wherein the linear finite state machine is a ring generator with multiple inputs.

57. The circuit recited in claim 53, wherein one of the one or more location data collectors is a failing word counter.

58. The circuit recited in claim 57, wherein the failing word counter includes a ring generator.

59. The circuit recited in claim 53, wherein one of the one or more location data collectors is a failing column indicator.

60. The circuit recited in claim 59, wherein the failing column indicator is configured not to record a column failure if the column failure is due to a partial row failure that extends over at least three adjacent vertical segments.

61. The circuit recited in claim 53, wherein one of the one or more location data collectors is a failing row indicator.

62. The circuit recited in claim 61, wherein the failing row indicator is configured to record a row-related error if the comparator outputs errors in three consecutive time frames.

63. The circuit recited in claim 53, further comprising one or more shadow registers that receive the compacted test response signatures from the signature register and unload the compacted test response signatures into an external ATE at sampling rates acceptable by the external ATE.

64. A method for testing memory arrays, comprising:
comparing test response data with expected test response data to generate test response signatures;
collecting the test response signatures in one or more location data collectors to generate error location information; and
collecting the test response signatures in a signature generator to generate compacted test response signatures.

65. The method recited in claim 64, further comprising:
determining fault locations based on the compacted test response signatures and the error location information.

66. The method recited in claim 64, further comprising:
loading the compacted test response signatures into a shadow register after a test run; and
unloading the compacted test response signatures into an external ATE at sampling rates acceptable by the external ATE.

67. The method recited in claim 64, wherein the signature register is a linear finite state machine.

68. The method recited in claim 67, wherein the linear finite state machine is a ring generator with multiple inputs.

69. A method for fault diagnosis of a memory array, comprising:
receiving a compacted test response signature generated by a signature register and error location information generated by one or more location data collectors;
determining a first distance between an initial state of the signature register and a first state of the signature register associated with the compacted test response signature;
selecting a reference signature based on the error location information;
determining a second distance between the initial state of the signature register and a second state of the signature register associated with the reference signature; and
determining a fault location based on the first distance and the second distance.

70. A method for fault diagnosis of a memory array, comprising:
receiving a compacted test response signature generated by a signature register and error location information generated by one or more location data collectors;
compiling a set of linear equations based on the error location information and the compacted test response signature; and
determining fault locations by solving the set of linear equations.

71. A method for fault diagnosis of a memory array, comprising:
receiving a compacted test response signature (St) generated by a signature register and error location information generated by one or more location data collectors;
determining whether a failing row and a failing column intersect based on the error location information; and
conducting following operations when there is a failing row and a failing column intersect:
retrieving row, column and cell signatures (Sr, Sc, and Si) from a lookup table;
forming an equation: St=Sr+Sc+Si; and
performing simulation with the equation to determine fault locations.
